(19) United States
(12) Patent Application Publication
(10) Pub. No.: US 2024/0329083 A1
(43) Pub. Date: Oct. 3, 2024

(54) STATIONARY PROBE, MOVABLE PROBE, AND PROBING DEVICE CAPABLE OF ADJUSTING THE DETECTING POSITION USING THE SAME

(71) Applicant: MPI CORPORATION, Zhubei City (TW)

(72) Inventors: CHIA-NAN CHOU, Zhubei City (TW); Chung-Yen Huang, Zhubei City (TW); Wen-Chin Yang, Zhubei City (TW); Wen-Hung LO, Zhubei City (TW); Wei-Lwen Yeh, Zhubei City (TW); Chih-Hao Ho, Zhubei City (TW)

(21) Appl. No.: 18/592,773

(22) Filed: Mar. 1, 2024

(30) Foreign Application Priority Data
Mar. 2, 2023 (TW) 112107676
Feb. 29, 2024 (TW) 113107331

(51) Int. Cl. G01R 1/067; G01R 1/073

(52) U.S. Cl. CPC G01R 1/06772; G01R 1/0675; G01R 1/07314

(57) ABSTRACT

A position-adjustable probing device comprises a stationary probe comprising a first coaxial structure having a first needle core, a first dielectric layer, and a first exterior conductive layer, and a first and a second movable probes. The first movable probe arranged at a first side of the stationary probe comprises a ground needle core, and a first extending structure comprising a first planar structure electrically contacted with the stationary probe through a first movement, a first top surface and a first bottom surface. The second movable probe arranged at a second side of the stationary needle comprises a second coaxial structure comprising a second needle core, a second dielectric layer, and a second exterior conductive layer, and a second extending structure comprising a second planar structure electrically contacted with the stationary probe through a second movement, a second top surface, and a second bottom surface.

This application claims the benefit of Taiwan Patent Application Serial 112107676, filed Mar. 2, 2023, and Ser. No. 11/310,7331, filed Feb. 29, 2024, the subject matter of which is incorporated herein by reference.

### BACKGROUND OF INVENTION

### 1. Field of the Invention

The present invention provides a probing device, and more particularly, to a stationary probe, movable probe, and probing device combining movable probe and stationary probe that is capable of automatically adjusting the relative position according to the pitch of the electrical contact pad of DUT.

### 2. Description of the Prior Art

Due to the miniaturization of electronic components, it is necessary to test device under test (DUT) after the semiconductor process to determine whether there are any issues in signal transmission, thereby the quality of electronic components. Generally, when it comes to test whether the electrical connections between various electronic components in electronic products are reliable, or if there are any issues with signal transmission, devices equipped with probes are typically used for analyzing signal transmission and electrical signal of the DUT.

Conventional testing equipment, including probe devices and signal testing machine, are utilized to test electrical characteristics of DUT. The probe device mainly comprises a plurality of probes used to make point contact with the contact pads of printed circuit boards. For high-frequency impedance testing, coaxial probes having a needle core and a ground conductor insulted around the needle core are adopted, and are electrically connected to the testing machine via coaxial signal cable. Typically, in the conventional configuration of probes, two probes form a set with a fixed spacing such that the needle tips of the two probes in the same set are very close to each other and their grounding conductors are mutually conductively connected.

However, due to the consideration of spatial layout or electrical characteristics of printed circuit boards, there is a wide variability in the spacing or angle between contact pads on the printed circuit board. This will also induce variability in spacing and angle of the probes that is required for impedance testing of printed circuit boards; therefore, it is necessary to prepare different probe configurations for accommodating diverse testing needs. In other words, when the spacing and angle of probes required for impedance testing of printed circuit boards are varied, different probing configuration has to be replaced, thereby resulting in higher costs of the testing machine.

In order to solve above-mentioned issues, in conventional techniques, as illustrated in FIG. 1A, there is a stationary probe 10 and a pair of movable probes 11 and 12. The stationary probe 10 is a signal probe with a coaxial structure. One of the movable probes 11 and 12 is a signal probe with a coaxial structure, while the other serves as a ground probe. Specifically, the stationary probe 10 comprises a conductor frame 100, a needle body 101, and ground conductors 102a and 102b. The conductor frame 100 is formed by solid metal. The conventional probe device 1 comprises a stationary probe conductor, and the conductor frame 100 has an object side 100a close to the DUT. The conductor frame 100 is located at the object side 100a, and ground conductors 102a and 102b are arranged on both sides of the needle body 101. The needle body 101 protrudes from the object side 100a of the conductor frame 100 to electrically contact one contact pad 90a at one end of the electrical structure on the circuit substrate 90c of the DUT 90. The needle tip 111 of the movable probe 11 electrically contacts another contact pad 90b at one end of the electrical structure on the circuit substrate 90c of the DUT 90. The needle tips 111 and 121 of the movable probes 11 and 12 can be moved closer to or moved away from the contact direction of the contact pad of the electrical structure through a first translation movement. The movable probes 11 and 12 are further comprises ground conductors 110 and 120, wherein the ground conductor 110 electrically contacts the ground conductor 102a on the conductor frame 100 during test, thereby allowing the movable probe 11 to form a detection loop with the stationary probe 10, while preventing the movable probe 12 from electrically contacting with the stationary probe 10, and the ground conductor 120 electrically contacts with the ground conductor 102b on the conductor frame 100 during the test thereby allowing the movable probe 12 to form a detection loop with the stationary probe 10, while preventing the movable probe 11 from electrically contacting with the stationary probe 10. In order to comply with the testing specifications for printed circuit boards, there are various kinds of pitches, such as pitches having greater interval or smaller interval, for example, between the stationary probe 10 and the movable probe 11 (or 12). As shown in FIG. 1A, the testing machine moves the movable probe 11 or 12 to change the pitch between the movable probe 11 or 12 such that the pitch is corresponding to the contact pitch. Furthermore, by extending the conductor frame 100 toward to both sides of the needle body 101, the ground portion of the movable probe 11 or 12 can contact the conductor frame 100 to form a signal loop. In the conventional art depicted in FIG. 1A, due to the solid metal conductor frame 100 of the stationary probe 10 having considerable weight, the stationary probe 10 is heavier than the movable probes 11 and 12. This will induce significant needle scrub being deeply formed on the surface of contact pad 90a due to the inertial force generated by momentum when the stationary probe is moved downwardly to contact the contact pad 90a. Consequently, it exacerbates the wear of needle tip 101, shortening thereby reducing the lifetime of the stationary probe 10. Additionally, since the weight of the stationary probe 10 is different from the movable probes 11 and 12, it will result in inconsistent needle scrub on contact pad 90a and will further lead to height difference when the stationary probe 10 and the movable probes 11 and 12 contact the contact pads 90a during the test, thereby causing the up-and-down fluctuation of positions of the movable probes 11 and 12 and resulting in unstable test results. Furthermore, the structure in FIG. 1A also leads to the formation of multiple signal loops between the conductor frame 100 and the movable probes 11 or 12, causing interference between the signal loops and affecting the test results.

In order to solve the aforementioned issues, in conventional art shown in FIG. 1B, a schematic diagram of a probing device of conventional art is provided. Through-holes 103a and 103b are opened on the conductor frame 100 to reduce the weight of the conductor frame 100. However, the weight of the stationary probe 10 is still much heavier than that of the movable probes 11 and 12. Therefore, when applying the same force to move movable probes 11 and 12 closer to the DUT, the result that the needle scrub on the contact pad 90a caused by the stationary probe 10 is deeper, while the needle scrub on the contact pad 90b generated by the movable probe 11 is shallower. This inconsistency between the needle scrub on contact pad 90a and contact pad 90b is obvious, and the problem of shortened lifetime of needle tip 101 still exists. In the structure shown in FIG. 1B, although the movable probes can be dynamically adjusted according to the pitch between contact pads 90a and 90b, there is still a problem of signal interference. For example, in FIG. 1B, the stationary probe 10 outputs a test signal to contact pad 90a, while the movable probe 11, representing the ground probe, contacts with the contact pad 90b electrically. During the test process, the signal loop L1 of test signal is formed by the stationary probe 10, the movable probe 11, the conductive structure around the through-hole 103a of the conductor frame 100, and the contact pads 90a and 90b. However, since the area around the through-hole 103b of the conductor frame 100 is also composed of conductive material, the signal loop L2 of the test signal is also formed by the conductive structure around the through-hole 103a of the stationary probe 10, the movable probe 11, the conductive structure around the through-hole 103b of the conductor frame 100, and the circuitry and contact pad 90a and 90b. Signal loop L2 interferes with signal loop L1, thereby affecting the test results. Conversely, if another movable probe 12, representing the ground structure 120 of the signal probe, electrically contacts with the ground structure 102b on the conductor frame 100 during testing, interference signal loop L1 is also similarly generated around through-hole 103a, as shown in FIG. 1C.

According to the issues described above, there is a need to provide a probing device with adjustable positions of contact test for meeting the testing specifications of printed circuit boards under the conditions of opening and closing pitches, thereby solving the issues occurred in the conventional art.

### SUMMARY OF THE INVENTION

In order to solve the issues described above, the present provides a position-adjustable probing device for meeting the test specification of PCB under condition of opening and closing pitches of PCB. Please refer to FIG. 2A, most part of the conductor frame 100 are removed, e.g. the part having a far distance away from the area of needle tip. It is noted that although the measure shown in FIG. 2A can eliminate weight of the conductor frame 100 and improve inconsistency of the scrub that was caused by the stationary probe 10 and movable probe 11 and 12 on the contact pad of DUT, it still can't completely eliminate the problem of signal interference. For example, in FIG. 2A, when the stationary probe 10 and movable probe 12 are controlled to test the DUT, an interference circuit L2 could still be occurred. Therefore, in one embodiment for solving this issue, such as shown in FIG. 2B, the part of the conductor frame for supporting the ground conductor 102a and 102b are further removed and the ground conductor 102a and 102b are only left. In this measure, it is indeed to solve the problem of signal interference; however, the strength of the ground conductors 102a and 102b will become weakened such that the structures are deformed thereby resulting in unstable of the testing result.

According to the above-described situation, the present invention provides a position-adjustable probing device for solving the inconsistency of the scrub occurred in the conventional arts thereby eliminating the interference signal and improving the strength of the stationary probe 10.

In one embodiment for solving the problem described above, the present invention provides a position-adjustable probing device comprising a stationary probe, a first movable probe, and a second movable probe. The stationary probe comprises a coaxial structure comprising a first needle core extending along a first central axis, and a first dielectric layer and a first exterior conductive layer, both coaxially surrounded the first needle core, wherein the first coaxial structure comprises a first side and a second side relative to the first central axis. The first movable probe arranged at the first side of the stationary probe further comprises a ground needle core extending along a second central axis, and a first extending structure coupled to the ground needle core. The first extending structure comprises a first planar structure, a first top surface, and a first bottom surface, wherein the first planar structure is arranged between the first top surface and the first bottom surface. One end of the ground needle core is the needle tip, and the first bottom surface is closer to the needle tip of the ground needle core than the first top surface. A first included angle is formed between the needle tip of the ground needle core and the first bottom surface, and the first planar structure is electrically contacted with the stationary probe through a first translation movement of the first movable probe. The second movable probe arranged at the second side of the stationary probe comprises a second coaxial structure and the second extending structure, wherein the second coaxial structure comprises a second needle core extending from a third central axis, and the second dielectric layer, and the second exterior conductive layer, both coaxially surrounded the second needle core. The second extending structure, coupled to the second exterior conductive layer, protrudes toward one specific direction from the second needle core, and comprises a second planar structure, the second top surface and the second bottom surface, wherein the second planar structure is arranged between the second top surface and the second bottom surface. One end of the second needle core is the needle tip, and the second bottom surface is closer to the needle tip of the second needle core than the second top surface. A second included angle is formed between the needle tip of the second needle core and the second bottom surface, and the second planar structure is electrically contacted with the stationary probe through a second translation movement of the second movable probe.

Through the previously described embodiment, the present invention eliminates the conductive metal structure around the through hole and changes the orientation of the conductive structure arranged on the stationary probe, such as the changing position of the probe body of the stationary probe to allow the central axis of the conductive structure perpendicular to the surface of the contact pad of the DUT through the planar structure of the stationary probe, for example, thereby preventing from extending toward two lateral sides of the contact pad of the DUT so as to solve insufficient strength issues of the conductive structure of the stationary probe after eliminating partial part of the conductor frame. Nevertheless, if the movable probe is not adjusted correspondingly, the issue that movable probe is not able to contact the stationary probe will be induced after the relative position between the movable probe and stationary probe is changed. Accordingly, in the previously described embodiment, an extending structure having ground conductor is protruded from a lateral side of the movable probe toward a lateral side of the stationary probe for electrically contacting with the ground conductor on the stationary probe during the signal test whereby the issue that the movable probe is not able to contact with the stationary probe can be solved. Through the previously described embodiments, the position-adjustable probing device of the present invention has the following effects:
(1). solving the inconsistency issues of the scrub on the surface of the contact pad of the DUT caused by the stationary probe and movable probe so as to prevent the test result from being unstable due to up and down fluctuation of the movable probe during the test;
(2). ensuring a circuit of signal test capable of being formed between the stationary probe and the movable probe electrically contacted with the stationary probe when the stationary probe and the movable probe are controlled to perform signal test so as to prevent interference circuit in the conventional art from being occurred, thereby achieving the effect of improving accuracy of signal test; and
(3). ensuring redesigned structure of the stationary probe can electrically connecting ground of the movable probe through structure of supporting surface.

The present invention provides a position-adjustable probing device, in which the conductive metal around the through hole of the stationary probe in the conventional art is removed, and in the periphery of both the stationary probe and movable probe, the plastic steel material is further utilized to replace the metal wrapping the probes whereby not only can the weight of the probe be reduced, but also the strength of the probe can be enhanced such that when the stationary probe contacts with the contact pad of the DUT, the needle scrub caused by the end of the probe on the surface of the contact pad can be reduced thereby preventing the electrical circuit and contact pad of DUT from being damaged and preventing the interference signal from being occurred.

Through the previously described embodiment, the arranged position and angle of the first movable probe are extending to the arranged position and angle of the stationary probe so as to lose the weight of stationary probe thereby achieving consistency of needle scrub and preventing interference signal circuit from being formed. Moreover, the first movable probe or the second movable probe is moved to electrically contacted with the ground of the stationary probe.

Through the previously describe embodiment, the end part on the third central axis of the second needle core is the needle tail. The second extending structure comprises a boundary surface on the second coaxial structure, wherein the distance from the boundary surface to the needle tip of the second needle core is smaller than the distance from the boundary surface to the needle tail of the second needle core. It is noted that, in the present embodiment, since the stationary probe and the second movable probe respectively have a first coaxial structure and a second coaxial structure, when the DUT is under the signal test, there is a need for frequency test. The closer the second extending structure is to the needle tip of the second movable probe, the position corresponding to the electrical contact of the stationary probe will also be closer to the needle tip of the stationary probe, whereby the electrical resolution ability for the DUT could be improved as the demand for frequency testing is getting higher.

Through the embodiment previously described, the second movable probe comprises a second isolation casing covering the second exterior conductive layer, wherein the second isolation casing comprises a partial tapered structure formed between the needle tip and needle tail of the second needle core while the second extending structure is arranged between the partial tapered structure and the second needle core. It is noted that the probe bodies of the present embodiment are covered by isolation casing such that the volume of the probe body will become too large. When the needle tip of the probe is vertically move down to contact with the DUT, the minimum pitch that the probe can move will be equal to the distance from the first needle core to the boundary of the probe body of the stationary probe plusing the distance from the second needle core to the probe body of the second movable probe. Since the volume of the probe body is too large, if the minimum pitch that the probe can move is larger than the default pitch of the contact pads of DUT, the signal test can't be proceeded. For example, if the default minimum pitch is smaller than the minimum pitch that the previously described probe can move, the signal test cannot be proceeded. Therefore, a non-vertical arrangement, i.e., tilting move to probe the DUT, should be configured between the probe itself and the DUT or supporting platform for supporting the DUT whereby the needle tip of the stationary probe and needle tip of the second movable probe can meet the test condition of the default pitch of the DUT. However, the non-vertical arrangement of the probe would induce the issues that the isolation casing close to the position of the needle tip would contact with the DUT before the needle tip contacting with the DUT such that the signal test can't be proceeded due to the interference of the needle tips. In the present embodiment, the partial tapered structure arranged close to the area of needle tip can solve the interference issues described above.

In one embodiment, the first movable probe comprises a metal block electrically connected to the ground needle core. A first extending structure is protruded from one lateral side of the metal block. One end part of the metal block on the central axis of the ground needle core is the needle tip of the ground needle core. The metal block comprises a partial tapered structure formed between another end part of the metal block and the needle tip of the ground needle core. The first extending structure protrudes from one lateral side of the partial tapered structure. It is noted that, in the present embodiment, since the stationary probe and the first movable probe respectively have a first coaxial structure and a ground needle core, when the DUT is under the signal test, there is a need for frequency test. The closer the first extending structure is to the needle tip of the first movable probe, the position corresponding to the electrical contact of the stationary probe will also be closer to the needle tip of the stationary probe, whereby the electrical resolution ability for the DUT could be improved as the demand for frequency testing is getting higher. In the present embodiment, the stationary probe and the first movable probe are tilted to probe the DUT such that the needle tips are mutually approaching to each other, while needle tails are moving away from each other whereby the needle tip can contact with the contact pad of the DUT under test condition of default minimum pitch of the DUT. Therefore, the issue that when the probes are vertically arranged, the volume of the stationary probe and the first movable probe is too large to narrow the pitch between the needle tips causing the needle tip cannot contact with the contact pad of the DUT under test condition of default minimum pitch of the DUT, can be avoided. Since the probe body of the stationary probe and the first movable probe has a specific bulk volume, if there has no design of the partial tapered structure, when the stationary probe and the first movable probe contact the contract pads of the DUT, the probe bodies will contact with the DUT such that the needle tip can't contact with the DUT thereby causing the interference between the probe and needle tip; therefore, in the present embodiment, through the design of the partial tapered structure, the effect that the needle tip contacts with the contact pad of the DUT but the probe body will not contact with the DUT can be achieved.

Through the embodiment described previously, the stationary probe comprises a holding part for holding the conductive structure. The holding part is arranged on the first exterior conductive layer and is electrically connected to the first exterior conductive layer. The holding part comprises a sloping surface, a top end part, and a bottom end part, wherein the sloping surface is arranged between the top end part and bottom end part. One end of the first needle core is the needle tip. The bottom end part is closer to the needle tip of the first needle core than the top end part. A first distance at the bottom end part is defined from the first exterior conductive layer to the sloping surface while a second distance at the top end part is defined from the first exterior conductive layer to the sloping surface, wherein the second distance is larger than the first distance.

Through the embodiment previously described, the stationary probe further comprises a conductive structure, and the first movable probe further comprises a first conductive structure, wherein the conductive structure of the stationary probe is arranged on the sloping surface, while the first conductive structure is arranged on the first planar structure. When the conductive structure of the stationary probe is electrically contacted with the first conductive structure, the conductive structure of the stationary probe is in point contact with the first conductive structure. The second movable probe further comprises a second conductive structure, wherein the conductive structure of the stationary probe is arranged on the sloping surface, while the second conductive structure is arranged on the second planar structure. When the conductive structure of the stationary probe is electrically contacted with the second conductive structure, the conductive structure of the stationary probe is in point contact with the second conductive structure. The second movable probe further comprises a second conductive structure arranged on the second planar structure, when the conductive structure of the stationary probe is electrically contacted with the second conductive structure, the conductive structure of the stationary probe is in point contact with the second conductive structure. It is noted that when the first movable probe or the second movable probe contacts with the stationary probe, the issue of unstable contact will be occurred due to the uneven contact surface; therefore, the sloping surface is arranged on the stationary probe for achieving effect of stable contact between the movable probe, e.g., the first movable probe or the second movable probe, and the stationary probe. In addition, the sloping surface also possesses blocking effect for blocking force that makes the movable probe, e.g., the first movable probe or the second movable probe, generating displacement toward the stationary probe thereby preventing the movable probe from being slipped.

In another embodiment, the conductive structure of the stationary probe can be a cylindrical rod-like conductor structure or can have a plurality of ball-like protrusions formed by linear arrangement. The first conductive structure can be a cylindrical rod-like conductor structure or can have a plurality of ball-like protrusions formed by linear arrangement. The second conductive structure can be a cylindrical rod-like conductor structure or can have a plurality of ball-like protrusions formed by linear arrangement.

In order to prevent the other probe from signal interference caused by stationary probe or the second movable probe, in another embodiment, the probe body of the stationary probe further comprises a first isolation casing and the second probe body comprises a second isolation casing, wherein the first isolation casing covers the first exterior conductive layer and the second isolation casing covers the second exterior conductive layer. The first and second isolation casings can be formed by plastic steel material.

Through the embodiments described previously, in order to support the structure strength of the stationary probe and the second movable probe, in one embodiment, a first reinforcement structure is arranged between the first isolation casing and the first exterior conductive layer, and a second reinforcement structure is arranged between the second isolation casing and the second exterior conductive layer. In addition to considering the strength of the probe structure, it is also necessary to consider the lightweighting for reducing the weight of the probe such that the consistency of the needle scrub can be achieved. The first reinforcement structure and the second reinforcement structure can be made by ceramic material.

In one embodiment, a reinforcement structure is further arranged in the first and second movable probes, wherein a third reinforcement structure is arranged at one side of the first planar structure of the first movable probe, and at one side of the second planar structure of the second movable probe. Furthermore, the first movable probe comprises a first extending structure, and the second movable probe comprises a second extending structure, wherein the first and the second extending structures adopt a sandwiched structure formed by the third reinforcement structure and metal conductor. The material for making the third reinforcement structure is ceramic material such that when the first movable probe or the second movable probe contacts the stationary probe, the first and second extending structures can be strengthened whereby the deformation caused by the exerted force generated due to the contact with the stationary probe can be avoided. In addition, the consideration of lightweighting on the probe weight is also necessary so as to achieve the consistency of the needle scrub.

In one alternative embodiment, the area closing the needle tip of the stationary probe further comprises two separated sloping surfaces formed at the first side and second side of the stationary probe, respectively. Each sloping surface has a conductive structure. The conductive structures formed on each sloping surface are corresponding to the first movable probe and the second movable probe, respectively. The first conductive structure of the first movable probe electrically contacts with the conductive structure arranged on the first side of the stationary probe, while the second conductive structure of the second movable probe electrically contacts with the conductive structure arranged on the second side of the stationary probe. Through the way that the first and second conductive structures electrically contact with the corresponding conductive structure on the stationary probe, respectively, the abrasion of conductive structure can be reduced so as to increase the utilization lifetime of the stationary probe. It is noted that when the first movable probe or second movable probe contacts with the stationary probe, the issue of unstable contact will be occurred due to the uneven contact surface; therefore, in the present embodiment, the sloping surface is arranged on the stationary probe for achieving effect of stable contact between the first movable probe and the stationary probe as well as the second movable probe and the stationary probe. In addition, the two sloping surfaces also possess blocking effect for blocking force that makes the displacement of the first or second movable probe toward the stationary probe thereby preventing the first or second movable probe from being slipped.

In one embodiment, the present invention further provides a stationary probe of a position-adjustable probing device, in which the position-adjustable comprises a movable probe for adjusting the pitch between the stationary probe and movable probe through translation movement. The movable probe further comprises a needle core extending along a central axis and an extending structure protruding toward one specific direction from the needle core. The stationary probe further comprises a first coaxial structure comprising a first needle core extending from a first central axis, and a first dielectric layer and first exterior conductive layer, both of which are coaxially surrounded the first needle core, wherein the first exterior conductive layer is configured to electrically contact with the extending structure of the movable probe. Through the previously described embodiment, the inconsistency of needle scrub formed on the surface of the contact pads of the DUT by the stationary probe and movable probe can be solved whereby unstable test results caused by the up-and-down fluctuation of positions of the movable probes can be prevented. In addition, when the stationary probe and movable probe proceeding the signal test, the circuit of the signal test formed between the stationary probe and movable probe electrically contacting with the stationary probe can be ensured such that the formation of the interference signal circuit in the conventional art can be avoided thereby achieving the effect of improving the accuracy of the signal test.

In one embodiment, after the pitch between the movable probe and stationary probe is adjusted by the movable probe through translation movement, the first exterior conductive layer is utilized to electrically contact with the extending structure of the movable probe, wherein, during the process that the movable probe is moved, the extending structure does not electrically contact with the first exterior conductive layer so as to prevent the contact interfaces of the movable probe and the stationary probe form being over rubbed to reduce the lifetime of utilization.

In one embodiment, the stationary probe further comprises a holding part arranged on the first exterior conductive layer for electrically connecting to the first exterior conductive layer. The holding part comprises a sloping surface, top end part, and bottom end part, wherein the sloping surface is arranged between the top end part and bottom end part. After the pitch between the movable probe and stationary probe is adjusted by the movable probe through the translation movement, the sloping surface is utilized to electrically contact with the extending structure of the movable probe. The end part of the first needle core is the needle tip. The bottom end part is closer to the needle tip of the first needle core than the top end part. A first distance on the bottom end part is defined from the first exterior conductive layer to the sloping surface while a second distance on the top end part is defined from the first exterior conductive layer to the sloping surface, wherein the second distance is larger than the first distance. It is noted that when the movable probe contacts with the stationary probe, the issue of unstable contact will be occurred due to the uneven contact surface; therefore, in the present embodiment, the effect of stable contact between the movable probe and the stationary probe is achieved through the sloping surface arranged on the stationary probe. In addition, the sloping surface also possesses blocking effect for blocking force that moves the movable probe toward the stationary probe thereby preventing the movable probe from being slipped.

In another alternative embodiment, the present invention provides a movable probe of a position-adjustable probing device comprising a stationary probe secured at a fixed position such that the pitch between the stationary probe and the movable probe is adjusted by moving the movable probe through a translation movement. The stationary probe comprises a first coaxial structure comprising a first needle core extending along a first central axis, and a first dielectric layer and first exterior conductive layer, both of which are coaxially surrounded first needle core. The movable probe comprises a needle core extending along a central axis and extending structure protruding toward one direction from the needle core, wherein the extending structure comprises planar structure, top surface, and bottom surface. The planar structure is arranged between the top surface and bottom surface. The end part of the needle core is the needle tip. The bottom surface is closer to the needle tip of the needle core than the top surface and an included angle is formed between the needle tip of the needle core and the bottom surface. The extending structure is utilized to electrically contact with the first exterior conductive structure. Through the previously described embodiment, the inconsistency of needle scrub formed on the surface of the contact pads of the DUT by the stationary probe and movable probe can be solved whereby unstable test results caused by the up-and-down fluctuation of positions of the movable probes can be prevented. In addition, when the stationary probe and movable probe proceeding the signal test, the circuit of the signal test formed between the stationary probe and movable probe electrically contacting with the stationary probe can be ensured such that the formation of the interference signal circuit in the conventional art can be avoided thereby achieving the effect of improving the accuracy of the signal test.

In one embodiment, after the pitch between the movable probe and the stationary probe is adjusted by the movable probe through the translation movement, the extending structure electrically contacts with the first exterior conductive layer, wherein during the process of the translation movement, the extending structure will not electrically contact with the first exterior conductive layer so as to prevent the contact interfaces of the movable probe and the stationary probe form being over rubbed to reduce the lifetime of utilization.

In one embodiment, the movable probe comprises a first movable probe comprising ground needle core extending along a second central axis, and a first extending structure. The needle core of the movable probe is the ground needle core, the extending structure of the movable probe is the first extending structure coupled to the ground needle core. After the pitch between the first movable probe and the stationary probe is adjusted by the first movable probe through the translation movement, the first extending structure electrically contacts with the first exterior conductive layer. The first extending structure comprises a first planar structure, a first top surface, a first bottom surface. The planar structure is the first planar structure, the bottom surface is the first bottom surface, and the top surface is the first top surface, wherein a first angle is formed between the needle tip of the ground needle core and the first bottom surface.

In one embodiment, the first movable probe comprises a metal block electrically connected to the ground needle core. On the central axis of the ground needle core, one end part of the metal block is the needle tip of the ground needle core. The metal block comprises a partial tapered structure formed between another end part of the metal block and the needle tip of the ground needle tip, and the first extending structure protrudes from one lateral side of the partial tapered structure. Since the stationary probe and the probe body of the first movable probe have a bulk volume, if there is no design of the partial tapered structure, when the stationary probe and the first movable probe are electrically contacted with the contact pads on the DUT, the interference between the probe body and needle tip will be caused because the probe body will contact with the DUT first but the needle tip can't contact with the DUT. Therefore, in the present embodiment, the effect that the needle tip can contact with the contact pad of DUT but the probe body won't contact with the DUT can be achieved through design of the partial tapered structure.

In one embodiment, the movable probe further comprises a second movable probe comprising a second coaxial structure having a second needle core extending along a third central axis, and a second dielectric layer and a second exterior conductive layer, both coaxially surrounded the second needle core, and a second extending structure. The needle core of the movable probe is the second needle core, and the extending structure of the movable probe is the second extending structure. The second extending structure is configured to be moved to electrically contact with the first exterior conductive layer after the pitch between the second movable probe and the stationary probe is adjusted by the second movable probe through the translation movement. The second extending structure is coupled to the second exterior layer, and the second extending structure comprises a second planar structure, a second top surface, and the second bottom surface, wherein the planar structure is the second planar structure, the top surface is the second top surface, the bottom surface is the second bottom surface, a second included angle is defined between the needle tip of the second needle core and the second bottom surface, and the included angle is the second included angle.

### BRIEF DESCRIPTION OF THE DRAWINGS

The present invention will now be specified with reference to its preferred embodiment illustrated in the drawings, in which:

FIG. 1A illustrates probing device of the conventional art;

FIG. 1B illustrates probing device of the conventional art;

FIG. 1C illustrates probing device of the conventional art;

FIGS. 2A and 2B illustrate different design of the probing device;

FIGS. 3A and 3B respectively illustrates different perspective of view position-adjustable probing device according to one embodiment of the present invention;

FIGS. 4A˜4C respectively illustrates stationary probe according to different embodiments of the present invention;

FIG. 4D illustrates structure of the stationary probe according to another embodiment of the present invention;

FIGS. 5A˜5B illustrates first movable probe according to different embodiments of the present invention;

FIGS. 6A and 6B respectively illustrates the second movable probe according to different embodiments of the present invention;

FIGS. 7A˜7D illustrate the operation of the position-adjustable probing device according to one embodiment of the present invention;

FIGS. 8A˜8B illustrate position-adjustable probing device according to another embodiment of the present invention; and

FIGS. 9A˜9B illustrate position-adjustable device according to another embodiment of the present invention.

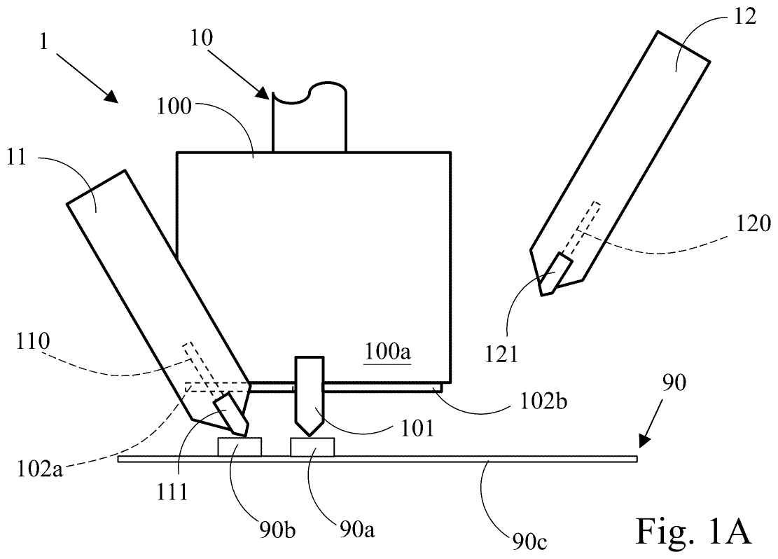

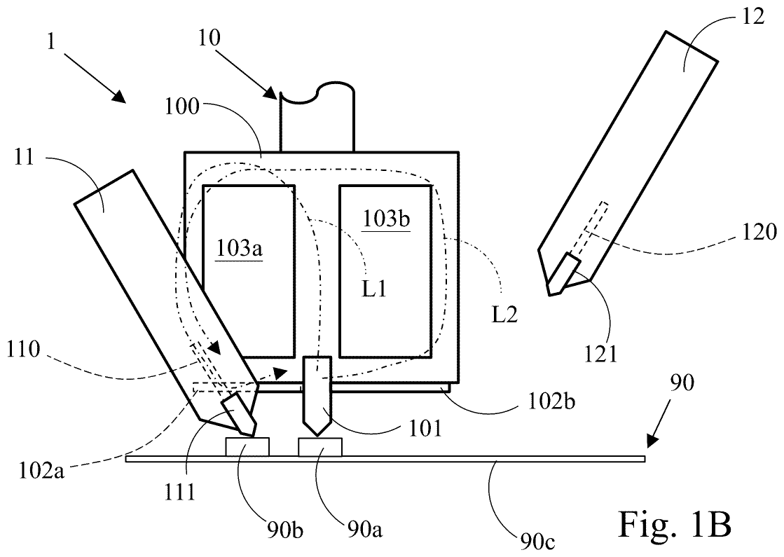

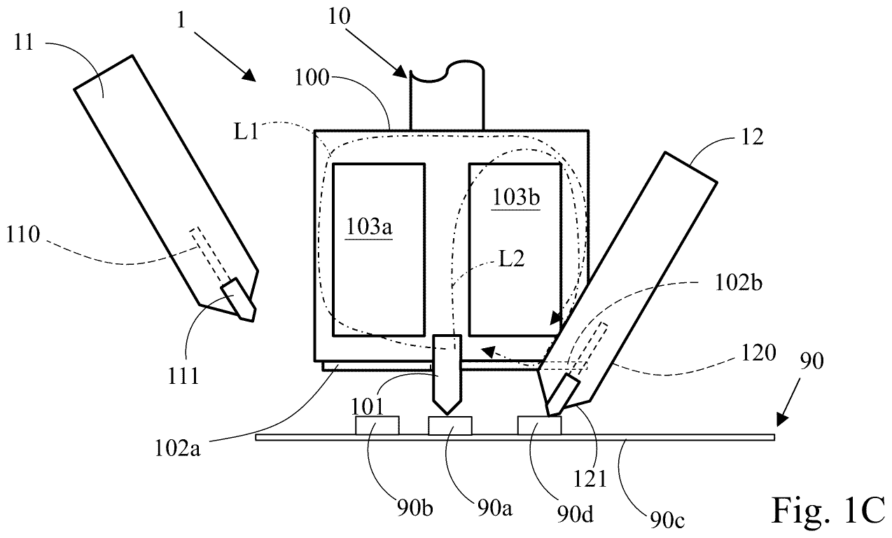

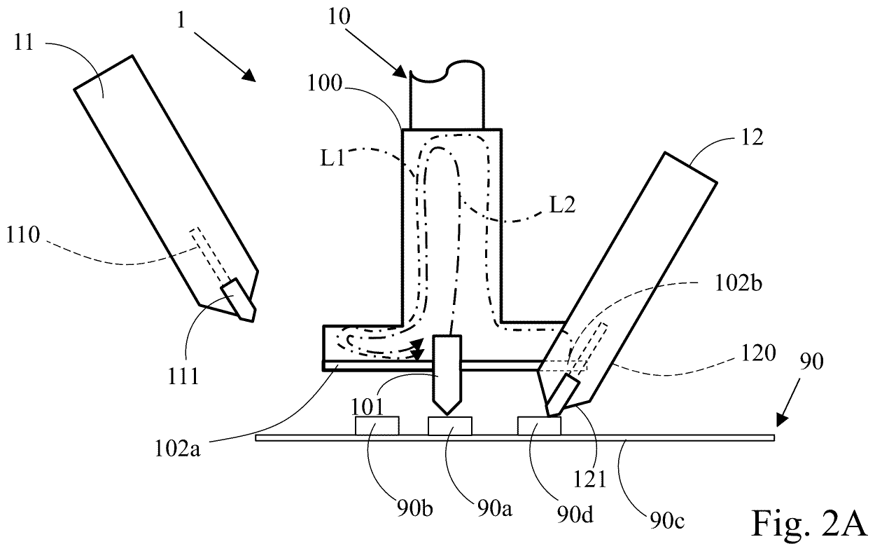

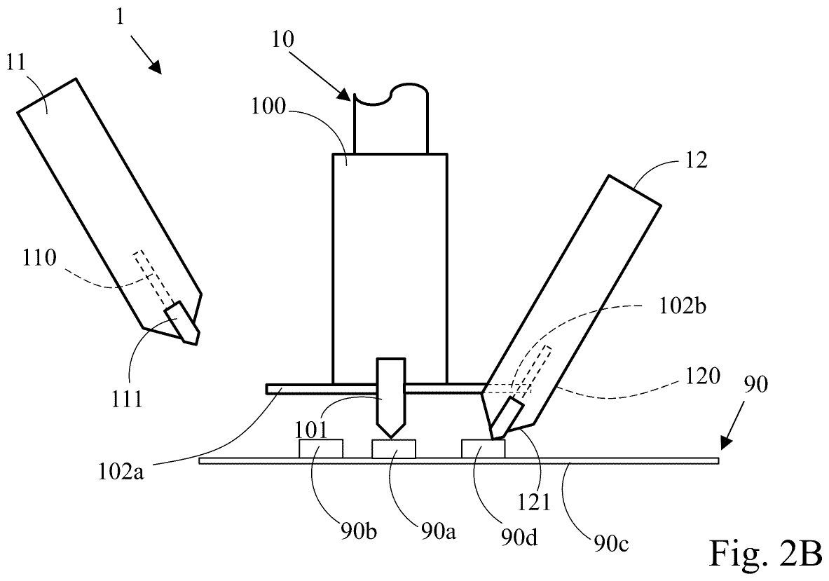

### DESCRIPTION OF THE PREFERRED EMBODIMENT

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a” “an” and “the” includes plural reference, and the meaning of “in” includes “in” and “on.” Titles or subtitles can be used herein for the convenience of a reader, which shall have no influence on the scope of the present disclosure. In addition, the terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first.” “second” or “third” can be used to describe various components, signals or the like, which are for distinguishing one component/signal from another one only, and are not intended to, nor should be construed to impose any substantive limitations on the components, signals or the like.

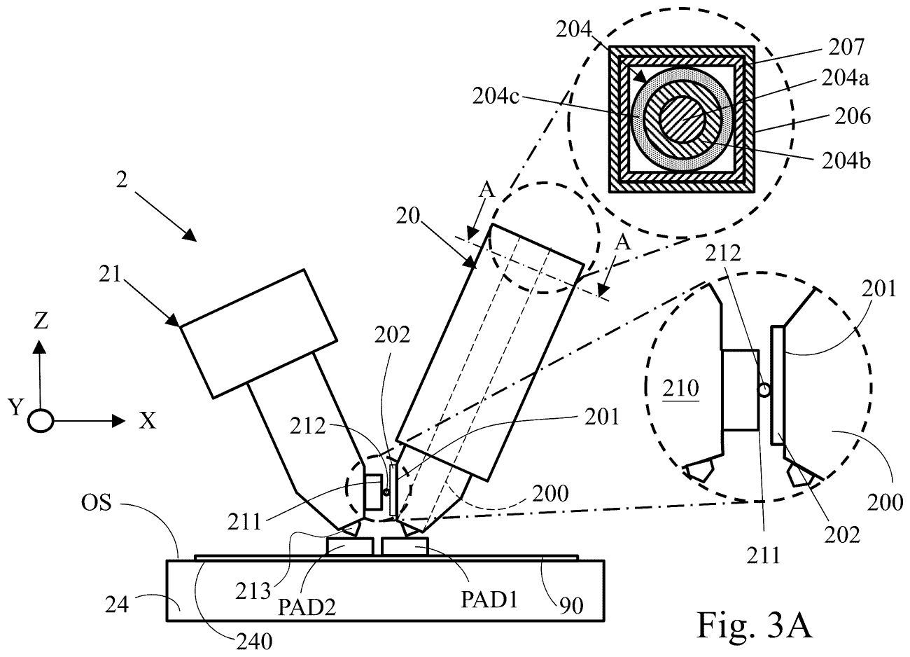

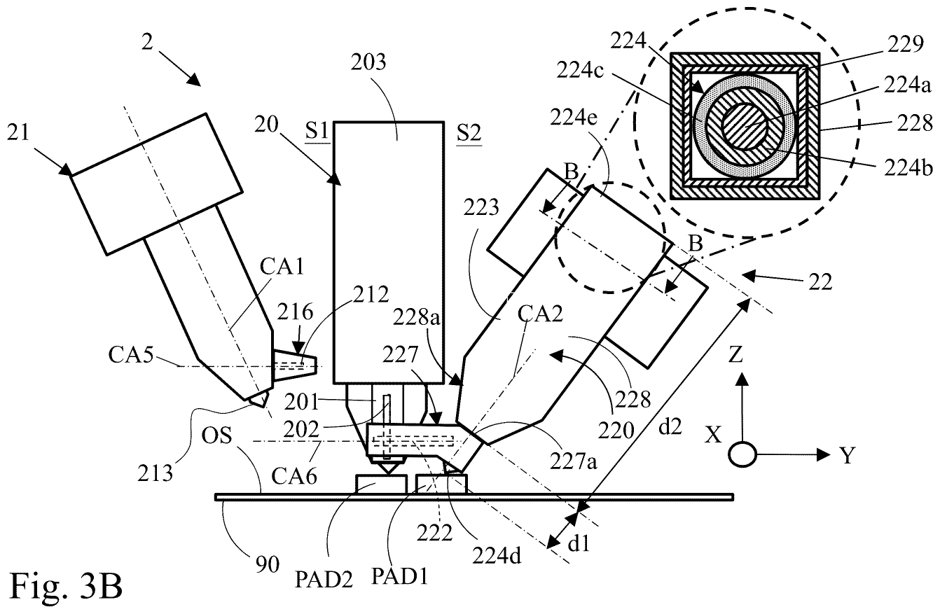

Please refer to FIGS. 3A and 3B, which illustrates different perspective of view of the position-adjustable probing device according to one embodiment of the present invention. In the present embodiment, probing device 2 comprises a plurality of probes for contacting reference plane alone X axis and Y axis. It is noted that the reference plane is one object surface OS formed on the DUT 90, or supporting plane 240 of the support platform 24 for supporting DUT 90. Taking surface plane OS of the DUT as an example, the probes of probing device 2 are utilized to electrically contacted the contact pads PAD1 and PAD2 formed on the object surface OS of DUT 90 for measuring electrical characteristics of the electrical structure formed on the object surface OS. In the present embodiment, the object surface OS further comprises a normal factor along a third axis Z which is perpendicular to the first axis X and the second axis Y. The probing device 2 comprises stationary probe 20, a first movable probe 21 and a second movable probe 22. In one embodiment, the DUT 90 is PCB, the electrical structure is referred to the trace formed on the PCB for transmitting the electrical signal. Generally speaking, contact pad is formed at the end of the trace. For example, the contact pads PAD1 and PAD2 shown in the FIG. 3A, in which one contact pad is for electrical contact of stationary probe 20 while the other one contact pad is for electrical contact of the movable probe such as the first movable probe 21 and/or the second movable probe 22 in the present embodiment. It is noted that the mechanism for driving the stationary probe 20, the first and second movable probes 21 and 22 is well known by the one having ordinary skilled in the art, such as the mechanism disclosed in the TW published application Ser. No. 20/211,5412, which will not be further described hereinafter.

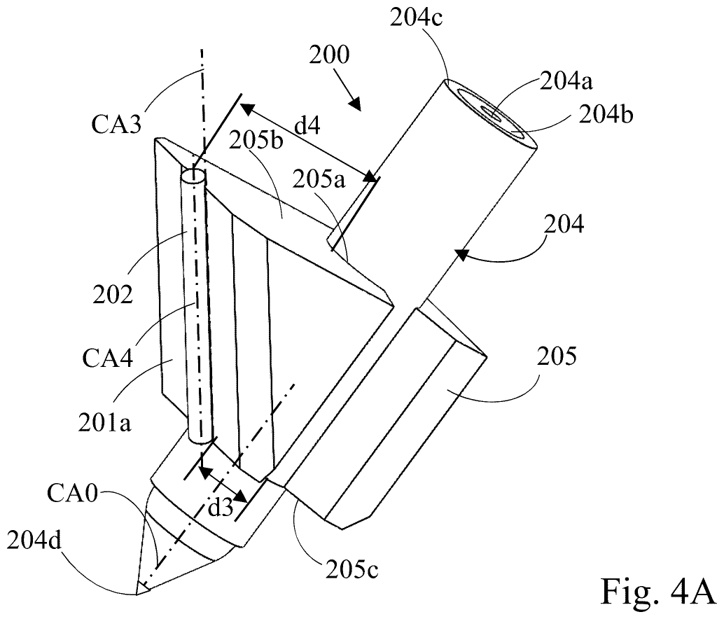

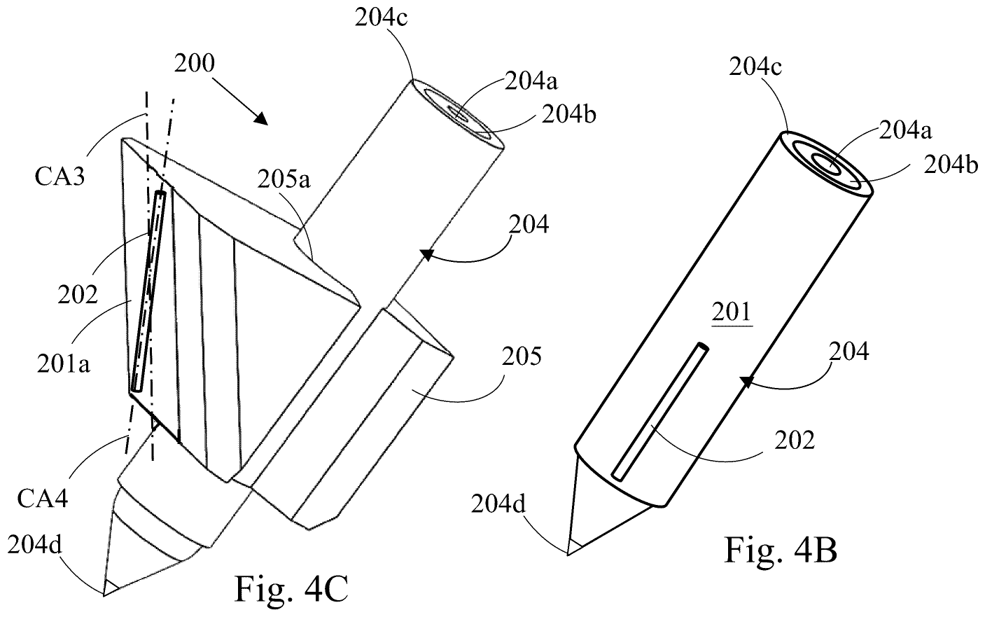

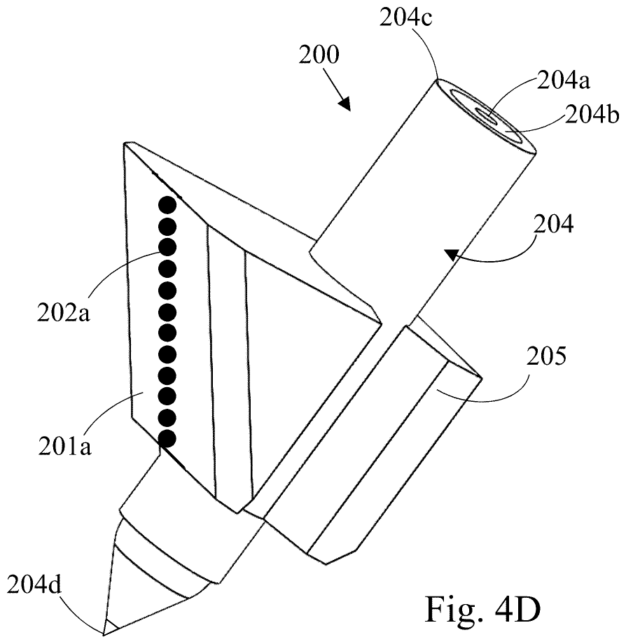

Please refer to FIGS. 3A˜3B and FIGS. 4A˜4C, the stationary probe 20 further comprises a probe body 200, supporting surface 201 formed on the probe body 200, and conductive structure 202 arranged on the supporting surface 201 without protruding out of the boundary of the supporting surface 201. The supporting surface 201, such as the sloping surface 201a shown in FIG. 4A, or first exterior conductive layer 204c shown in FIG. 4B, is configured to completely act as a supporting structure for supporting the conductive structure 202 so as to prevent the conductive structure 202 from being deformed or damaged due to contacting with the conductive structures of the other movable probe during the signal test.

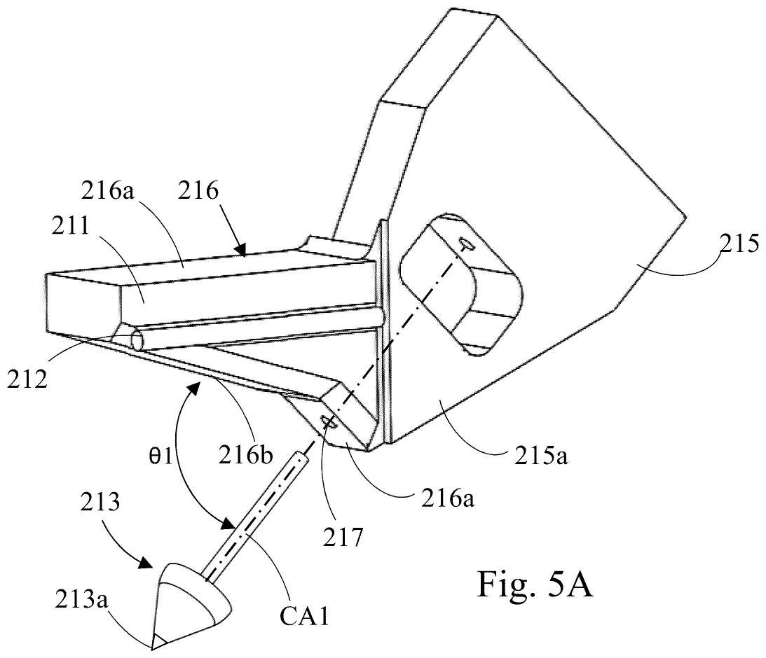

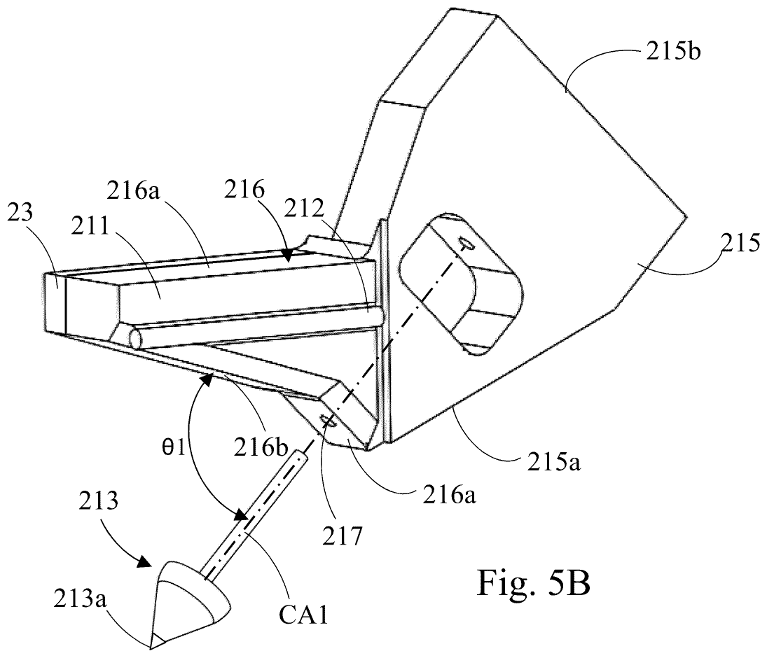

Please refer to FIGS. 3A˜3B and FIG. 5A, in which the FIG. 5A illustrates first movable probe according to one embodiment of the present invention. In the present embodiment, the first movable probe 21 comprises a first probe body 210, a first planar structure 211 protruded out of the lateral side of the first probe body 210, and a first conductive structure 212 arranged on the first planar structure 211. The first conductive structure 212 is electrically contacted the conductive structure 202 of the stationary probe 20 through a first translation movement of the first movable probe 21.

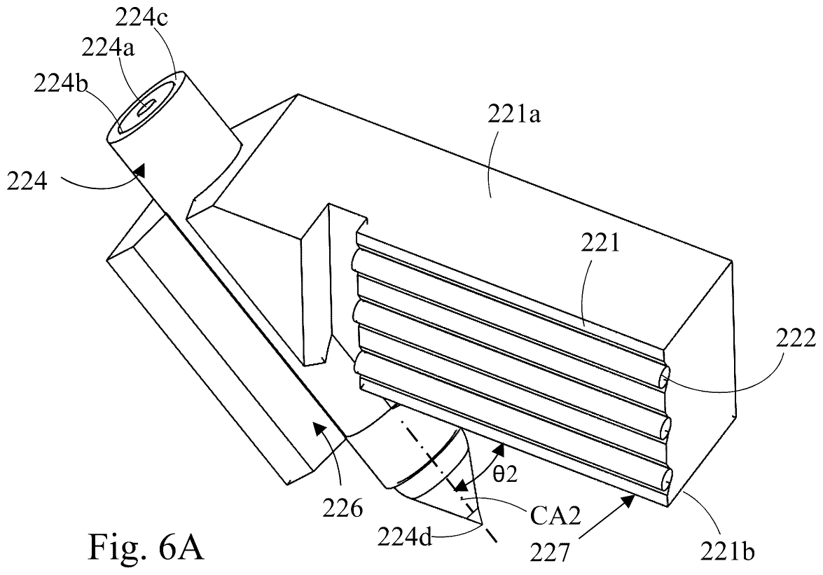

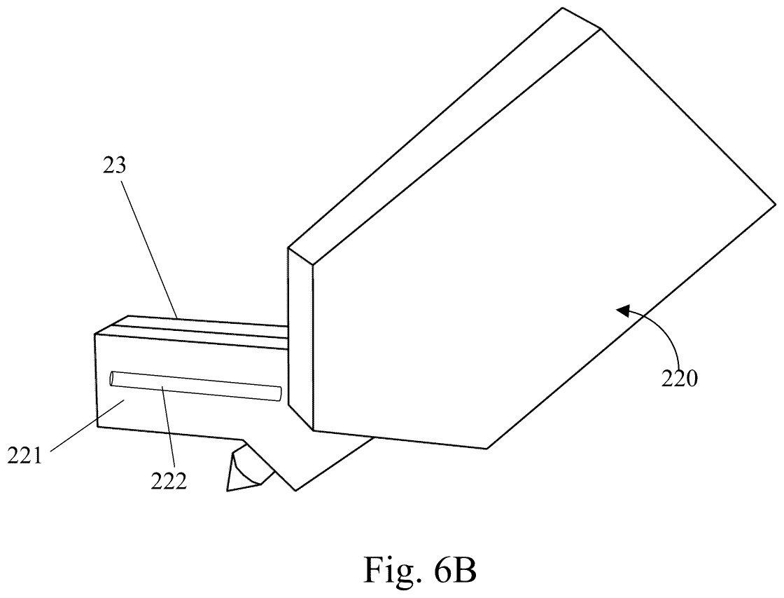

Please refer to FIGS. 3A˜3B and FIG. 6A, in which FIG. 6A illustrates the second movable probe according to another embodiment of the present invention. In the present embodiment, the second movable probe 22 comprises a second probe body 220, a second planar structure 221 protruded out of the lateral side of the second probe body 220, and a second conductive structure 222 arranged on the second planar structure 221. The second conductive structure 222 is electrically contacted the conductive structure 202 of the stationary probe 20 through a second translation movement of the second movable probe 22.

It is noted that, in one embodiment of the test process, the stationary probe 20 is paired with one of the first movable probe 21 or second movable probe 22. For example, when the stationary probe 20 is paired with the first movable probe 21 for performing SG test, in which S represents signal functioned by the stationary probe 20, while G represents ground functioned by the first movable probe 21, the second movable probe 22 should move towards the direction away from PAD1 and PAD2 formed on the object surface OS of the DUT so as to prevent the damage from being occurred due to the contact between the second movable probe 22 and the DUT 90. Alternatively, in another condition that SS test is conducted by stationary probe 20 and second movable probe 22, in which S represents signal, the first movable probe 21 should move towards the direction away from PAD1 and PAD2 formed on the object surface OS of the DUT.

Please refer to FIGS. 3A˜3B and FIG. 4A, in the present embodiment, the probe body 200 comprises a first coaxial structure 204 further comprising a first need core 204a extending along a first central axis CA0 of the first coaxial structure 204, and a first dielectric layer 204b and first exterior conductive layer 204c, both coaxially surrounded the first needle core 204a. The first coaxial structure 204 of the stationary probe 20 comprises a first side S1 and second side S2 relative to the first central axis CA0. The probe body 200 further comprises a holding part 205 electrically connected to the first exterior conductive layer 204c through a way that the holding part 205 is sleeved on the first exterior conductive layer 204c or the holding part 205 and the first exterior conductive layer 204c are integrally formed in one piece. The holding part 205 further comprises a sloping surface 201a, top end part 205b, and bottom end part 205c, wherein the sloping surface 201a is formed between the top end part 205b and bottom end part 205c. One end part of the first needle core 204a is the needle tip 204d, the bottom end part 205c is closer to the needle tip 204d of the first needle core 204a than the top end part 205b. At the bottom end part 205c, the first distance d3 is defined from the first exterior conductive layer 204c to sloping surface 201a. Athe top end part 205b, a second distance d4 is defined from the first exterior conductive layer 204c to the sloping surface 201a. The second distance d4 is larger than the first distance d3. In the present embodiment, the central axis CA3 of the sloping surface 201a along longitudinal axial direction is not parallel to the first central axis CA0 of the first needle core 204a wherein an included angle formed by the intersection of extension part of the central axis CA3 and first central axis CA0 is acute angle. In the present embodiment, the supporting surface 201 is the sloping surface 201a such that an included angle larger than 0 degree is formed by the central axis CA4 of the conductive structure 202 and the first central axis CA0 of the first needle core 204a. The width of the supporting surface 201 is larger than the width of the conductive structure 202. It is noted that when the first movable probe 21 or the second movable probe 22 is moved to contact with the stationary probe 20, the unstable contact will be occurred due to the uneven contact surface; therefore, the sloping surface 201a is arranged on the stationary probe 20 such that the stable contact effect could be achieved between the stationary probe 20 and movable probe, such as first movable probe 21 or second movable probe 22, for example. In addition, the sloping surface 201a also possesses blocking effect for blocking force that moves the first movable probe 21 or second movable probe 22 toward the stationary probe 20 thereby preventing the movable probe, such as first movable probe 21 or second movable probe 22, from being slipped.

In the present embodiment, the holding part 205 further comprises an inner contact surface 205a facing the first exterior conductive layer 204c. The holding part 205 is an electrically conductive material for electrically connecting to the first exterior conductive layer 204c. In addition, a specific section of the first exterior conductive layer 204c is enclosed by a first isolation casing 206. In the present embodiment, the first isolation casing 206 is made by plastic steel material which has isolation effect for preventing the interference signal from being occurred and having strength for protecting the probe body 200 of the stationary probe 20. Moreover, the plastic steel material also has effect of losing weight of the stationary probe 20 such that when the stationary probe 20 is moved down to contact with the contact pad, the scrub mark formed by the needle tip 204d of the stationary probe 20 on the surface of the contact pad, such as PAD2, could be reduced whereby the damage on the circuit and contact pad can be eliminated, and the weight of the stationary probe 20 could be similar to the first movable probe 21 and second movable probe 22 such that the consistency of the scrub could be achieved. In the present embodiment, in order to strengthen the probe body 200 of the stationary probe, a first reinforcement structure 207 is further formed between the first isolation casing 206 and the first exterior conductive layer 204c. In one embodiment, the first reinforcement structure 207 is formed by ceramic material. In the present embodiment, in order to reduce the weight of the stationary probe 20, the holding part 205 is arranged at a partial area of the first exterior conductive layer 204c for reducing the volume of the holding part 205 thereby reducing the weight of the metal material utilized by the holding part 205. Moreover, the holding part 205 is further arranged on the first exterior conductive layer 204c, and is arranged between the needle tip 204d of the stationary probe 20 and the first isolation casing 206. The structure, such as an opening, is formed on the holding part 205, the first coaxial structure 204 could be inserted into the inner contact surface 205a of an accommodating slot through the opening of the holding part whereby the first coaxial structure 204 could be arranged on the accommodating slot so as to secure the relative position between the first coaxial structure 204 and the holding part 205.

It is noted that, the conductive structure 202 is not limited by the arrangement illustrated in the FIG. 4A. For example, in one alternative embodiment shown in FIG. 4B, according to the designing spirit for strengthening the conductive structure, the conductive structure 202 is designed under the spirit without exceeding the boundary of the sloping surface 201a, wherein an included angle could be formed between the central axis CA4 along the longitudinal direction of the conductive structure 202 and the central axis CA3 along the longitudinal direction of the sloping surface 201a. In one alternative embodiment, please refer to FIG. 4C, which illustrates the stationary probe according to another embodiment of the present invention. In the present embodiment, the difference from the previously described embodiment is that the supporting surface 201 is the exterior surface of the first conductive layer 204c, and the conductor structure 202 of the stationary probe is electrically connected to the first exterior conductor layer 204c through a fixed means, such as soldering or electrical connections. It is noted that the conductive structure 202 is not limited to the cylindrical rod-like conductor structure in the previously describe structure. Alternatively, in the example shown in FIG. 4D, it illustrates the conductive structure according to another embodiment of the present invention. In this embodiment, the conductive structure 202 has a plurality of ball-like protrusions 202a formed by linear arrangement.

Please refer to FIGS. 3A and 3B, and FIG. 5A and FIG. 5B. In the present embodiment, the first movable probe 21 arranged at the first side S1 of the stationary probe 20 comprises a ground needle core 213 extending along the direction of the second central axis CA1, and a first extending structure 216, coupled to the ground needle core 213. In the present embodiment, the first movable probe 21 comprises a metal block 215. The ground needle core 213 is electrically connected to the ground metal block 215. The metal block 215 is utilized to strengthen the structure of the ground needle core 213. In one embodiment, the ground needle core 213 and metal block 215 are separated from each other. Alternatively, the ground needle core 213 and metal block 215 could be integrally formed in one piece. The first extending structure 216 protrudes from one side of the metal block 215. One end part on the second central axis CA1 of the metal block 215 is the needle tip 213a of the ground needle core 213. The metal block 215 further comprises a partial tapered structure 215a formed between another end part 215b of the metal block 215 and the needle tip 213a of the ground needle core 213, wherein the first extending structure 216 is protruded from one lateral side of the partial tapered structure 215a. The first extending structure 216 arranged on the metal block 215 comprises a boundary surface 216a, wherein the distance from the boundary surface 216a of the first extending structure 216 to the needle tip 213a of the ground needle core 213 is smaller than the distance from the boundary surface 216a of the first extending structure 216 to another end part 215b of the metal block 215.

In the present embodiment, since the stationary probe 20 and the first movable probe 21 respectively comprise first coaxial structure 204 and ground needle core 213, when the process of testing the DUT is proceeded, there is a need for frequency test. The closer the first extending structure 216 is to the needle tip 213a of the first movable probe 21, the position corresponding to the electrical contact of the stationary probe 20 will also be closer to the needle tip 204d of the stationary probe 20, whereby the electrical resolution ability for the DUT could be improved as the demand for frequency testing is getting higher.

In the present embodiment, the volume of the stationary probe 20 and the first movable probe 21 are larger than the needle tips 204d and 213a. When the two probes are vertically arranged, if the pitch between the two probes are shortened or even shortened to the pitch limit, the both probe bodies of the two probes will contact first; therefore, the pitch between needle tip 204d and 213a can't be shortened any further due to the interference of both probe bodies such that the testing condition that the small pitch between contact pads cannot be implemented. In order to solve the previously described issue, the stationary probe 20 and the first movable probe 21 are tilted to probe the DUT for avoiding the previously described issues, i.e., the needle tip 204d and 213a mutually approaching to each other, while needle tail 203 of the stationary probe 20 and the needle tail 205b of the first movable probe moving away from each other. In other words, the pitch between the needle tip 204d on the first central axis CA0 and needle tip 213a on the second central axis CA1 is smaller than the pitch between the needle tail 203 on the first central axis CA0 and needle tail 215b on the second central axis CA1. Since the pitch between the needle tails 203 and 215b broadens the distance between the stationary probe 20 and first movable probe 21, when the pitch between two probes are adjusted, especially to shorten the pitch, the contact between the probe bodies of the two probes are avoided so as to avoid the contact of the probe bodies of the two probes thereby preventing the movement of the needle tips from being interfered such that the needle tip 204d and needle 213a can be adjusted to the default pitch. Since the probe body of the first movable probe 21 has a volume, when the movable probe 21 is tilted to move toward the DUT and contacts with the contact pad of DUT, the probe body would contact with the DUT 90 first such that needle tip 213a can't contact with the DUT so as to cause the interference between probe body and needle tip 213a. Through the design of the partial tapered structure 215a, the effect that the needle tip 213a can contact with the contact pad of DUT 90 but the probe body would not contact with the DUT 90 can be achieved.

In the present embodiment, the first extending structure 216 protrudes toward one direction from the ground needle core 213. The first extending structure 216 has a planar structure 211, a first top surface 216a, and a first bottom surface 216b, wherein the planar structure 211 is arranged between the first top surface 216a and the first bottom surface 216b. One end of the ground needle core 213 is the needle tip 213a. The first bottom surface 216b is closer to the needle tip 213a of the ground needle core 213 than the first top surface 216a. A first included angle θ1 greater than zero degree is formed between the needle tip 213a of the ground needle core 213 and the first bottom surface 216b. The first planar structure 211 is electrically contacted with the stationary probe 20 through a first translation movement of the first movable probe 21. In the present embodiment, since the conductive structure 202 is arranged on the sloping surface 201a, and the first conductive structure 212 is arranged on the first planar structure 211, when the conductive structure 202 of the stationary probe 20 is electrically contacted with the first conductive structure 212, the conductive structure 202 is in electrical point contact with the first conductive structure 212. The first extending structure 216 can be a reinforcement structure for strengthening the structure of the first conductive structure 212. It is noted that, the first conductive structure 212 is a cylindrical rod-like conductor structure in the previously described embodiment, but it is not limited thereto. For example, the conductive structure 212 shown in FIG. 4D has a plurality of ball-like protrusions formed by linear arrangement. Please refer to FIG. 5B, which illustrates the first movable probe according to another embodiment of the present invention. In the present embodiment, the difference part from the previously described embodiment is that a third strengthen structure 23 is arranged at one side of the first planar structure 211. In one embodiment, the third reinforcement structure 23 is formed by ceramic material, which can improve the strength of the first extending structure 216 so as to prevent deformation of first extending structure 216 when the stationary probe 20 contacts with the first movable probe 21. In addition, it can also achieve lightweighting probe for keeping the consistency of the needle scrub.

Please refer to FIGS. 3A˜3B and FIG. 6A, in which FIG. 6A refers to the second movable probe according to another embodiment of the present invention. In the present embodiment, the second movable probe 22 is arranged at the second side S2 of the stationary probe 20. The second movable probe 22 comprises a second coaxial structure 224 and the second extending structure 227, wherein the second coaxial structure 224 comprises a second needle core 224a extending along a third central axis CA2 of the second movable probe 224, and a second dielectric layer 224b and a second exterior conductive layer 224c, both coaxially surrounded the second needle core 224a. The second extending structure 227 is coupled to the second exterior conductive layer 224c. The second extending structure 227 protrudes toward one direction from the second needle core 224a. Furthermore, the second extending structure 227 protrudes toward one direction from the second exterior conductive layer 224c. The second extending structure 227 further comprises a second planar structure 221, the second top surface 221a and the second bottom surface 221b, wherein the second planar structure 221 is arranged between the second top surface 221a and the second bottom surface 221b. One end part of the second needle core 224a is the needle tip 224d. The second bottom surface 221b is closer than the needle tip 224d than the second top surface 221a. A second included angle θ2 greater than zero degree is formed between the needle tip 224d of the second needle core 224a and the second bottom surface 221b. The second planar structure 221 is electrically contacted with the stationary probe 20 through a second translation movement of the second movable probe 22. In the present embodiment, the second extending structure 227 comprises an accommodating slot 226a for accommodating the second coaxial structure 224 such that the relative position between the second coaxial structure 224 and the second extending structure 227 is secured. The second movable probe 22 further comprises a second conductive structure 222. The conductive structure 202 is arranged at the sloping surface 201a while the second conductive structure 222 is arranged on the second planar structure 221. When the conductive structure 202 of the stationary probe 20 is electrically contacted with the second conductive structure 222, the conductive structure 202 of the stationary probe 20 is in electrical point contact with the second conductive structure 222. It is noted that the second conductive structure 222 described in the previous embodiment is a cylindrical rod-like conductor structure, but it is not limited thereto. For example, the second conductive structure can also be the previously described structure having a plurality of ball-like protrusions formed by linear arrangement shown in FIG. 4D.

In the present embodiment, the needle tail 224e is formed on another end of the second needle core 224a on the third central axis CA2. The second extending structure 227 arranged on the second coaxial structure 224 comprises a boundary surface 227a, wherein the distance d1 from the boundary surface 227a to the needle tip 224d of the second needle core 224a is smaller than the distance d2 from the boundary surface 227a to the needle tail 224e of the second needle core 224a. In addition, in the present embodiment, a specific section of the second exterior conductive layer 224c is covered by the second isolation casing 228. In the present embodiment, the second isolation casing 228 is made by plastic steel material that has isolation effect and strength for protecting the probe body 220 of the second movable probe 22. Moreover, the plastic steel material also has effect of losing weight of the second movable probe 22 such that when the second movable probe 22 is moved down to contact with the contact pad, the scrub mark formed by the needle tip of the second needle probe 22 on the surface of the contact pad, such as PAD1, could be reduced whereby the damage on the circuit and contact pad can be eliminated. In the present embodiment, in order to strengthen the probe body 220 of the second movable probe 22, a second reinforcement structure 229 is further formed between the second isolation casing 228 and the second exterior conductive layer 224c. In one embodiment, the second reinforcement structure 229 is formed by ceramic material. In the present embodiment, the second isolation casing 228 further has a partial tapered structure 228a which is arranged between the needle tip 224d of the second needle core 224a and second needle tail 224e of the second needle core 224a. The second extending structure 227 is arranged between the partial tapered segment 228a and the second needle tip 224d of the second needle core 224a.

In the present embodiment, since the stationary probe 20 and the second movable probe 21 respectively comprise the first coaxial structure 204 and the second coaxial structure 224, when test is proceeded, there is a need for frequency test. The closer the second extending structure 227 is to the needle tip 224d of the second movable probe 22, the position corresponding to the electrical contact of the stationary probe 20 will also be closer to the needle tip 204d of the stationary probe 20, whereby the electrical resolution ability for the DUT could be improved as the demand for frequency testing is getting higher.

In the present embodiment, since the stationary probe 20 and the second movable probe 21 respectively have first isolation casing 206 and the second isolation casing 228, both of which have bulk volume. If the stationary probe 20 and the second movable probe 22 are moved along the direction vertical to the DUT 90 or supporting platform 24 to probe the DUT, the minimum distance that the stationary probe 20 and the second movable probe 22 are available to move is equal to the distance from the first needle core 204a to the boundary of the probe body of the stationary probe 20 plusing the distance from the second needle core 224a to the probe body of the second movable probe 22. It is noted that when the pitch between the two probes is shortened to the limit pitch, the probe bodies of the two probes will mutually contact to interfere with needle tips 204d and 224d such that the pitch cannot be shorten anymore, which causes the intended condition of small pitch on the DUT could not be implemented. The stationary probe 20 and the second movable probe 22 are tilted to probe the DUT could solve the previously described issue. The needle tip 204d and 224d are mutually approaching to each other, while needle tail 203 of the stationary probe 20 and the needle tail 224e of the second movable probe 22 are moving away from each other. In other words, the pitch between the needle tip 204d and 224d is smaller than the pitch between the needle tail 203 and 224e through tilting the probes to contact with the DUT. Since the pitch between the needle tails 203 and 224d broadens the distance between the stationary probe 20 and the second movable probe 22, when the pitch between two probes is adjusted, especially to shorten the pitch, the contact between the probe bodies of the two probes can be avoided thereby preventing the movement of the needle tips from being interfered such that the needle tip 204d and needle 224d can be adjusted to the desired pitch. Since the probe body of the second movable probe 22 has a volume, when the second movable probe 22 is tilted to move toward the DUT and contacts with the contact pad of DUT 90, the probe body would contact with the DUT 90 first such that needle tip 224d can't contact with the DUT so as to cause the interference between probe body and needle tip 224d. Through the design of the partial tapered structure 228a, the effect that the needle tip 224d can contact with the contact pad of DUT 90 but the probe body doesn't contact with the DUT 90 can be achieved. Please refer to FIG. 6B, which illustrates the second movable probe according to another embodiment of the present invention. In the present embodiment, the difference part is that a third reinforcement structure 23 is arranged at one side of the second planar structure 221. In one embodiment, the third reinforcement structure 23 is made by ceramic which can improve the strength of the second extending structure 227 so as to prevent deformation of second extending structure 227 when the stationary probe 20 contacts with the second movable probe 22. In addition, it can also achieve lightweighting probe for keeping the consistency of the needle scrub. In one embodiment, in order to reduce the weight of the second movable probe 22, a second holding part 205 is arranged at a partial area of the second exterior conductive layer 224c for reducing the volume of the second holding part 226 thereby reducing the weight of the metal material utilized by the second holding part 226. Moreover, the second holding part 226 is further arranged on the second exterior conductive layer 224c and is arranged between the needle tip of the second movable probe 22 and the second isolation casing 228.

Please refer to FIGS. 3A˜3B and FIGS. 4A˜4C, the first coaxial structure 204 is formed by the first dielectric layer 204b coaxially surrounding the first needle core 204a, and the first exterior conductive layer 204c coaxially surrounding the first dielectric layer 204b. One end of the probe body 200 is the needle tip 204d while the other end is the needle tail. The needle tip 204d of the probe body 200 of the stationary probe 20 is the end part of the first coaxial structure 204 for contacting with the contact pad of the DUT 90, while the needle tail 203 of the probe body 200 is another end part of the first coaxial structure 204.

Please refer to FIGS. 3A˜3B and FIGS. 6A˜6B, the second coaxial structure 224 is formed by the second dielectric layer 224b coaxially surrounding the second needle core 224a, and the second exterior conductive layer 224c coaxially surrounding the second dielectric layer 224b. One end of the probe body 220 is the needle tip 224d while the other end is the needle tail 224e. The needle tip 224d of the probe body 220 of the second movable probe 22 is the end part of the second coaxial structure 224 for contacting with the contact pad of the DUT 90, while the needle tail 224e of the probe body 220 is another end part of the second coaxial structure 224.

Please refer to FIGS. 3A˜3B and FIGS. 5A˜5B, one end of the first probe body 210 is the needle tip 213a, while the other end is the needle tail. The needle tip 213a of the first probe body 210 is the end part of the ground needle core 213 for contacting with the contact pad of DUT 90. The needle tail of the first probe body 210 is the end of the metal block 215 that is far away from the ground needle core 213, i.e. another end part 215b of the metal block 215. In the present embodiment, most part of the first probe body 210 is made by metal material; therefore, the weight of the first movable probe 21 is heavier than the weight of the stationary probe 20 or the weight of the second movable probe 22 under the condition that the dimension of the stationary probe 20, the first movable probe 21, and the second movable probe 22 are the same as each other. In order to ensure the consistency of the needle scrub made by the stationary probe 20, first movable probe 21, and the second movable probe 22, the length of the first movable probe 21 is shortened thereby reducing the weight of the conductive material. In another words, the length from the needle tip to the needle tail of the first probe body 210 is smaller than the length from the needle tip to needle tail of the first coaxial structure 204 of the probe body of the stationary probe 20 while the length from the needle tip to the needle tail of the first probe body 210 is smaller than the length from the needle tip to needle tail of the second coaxial structure 224 of the second probe body 220.

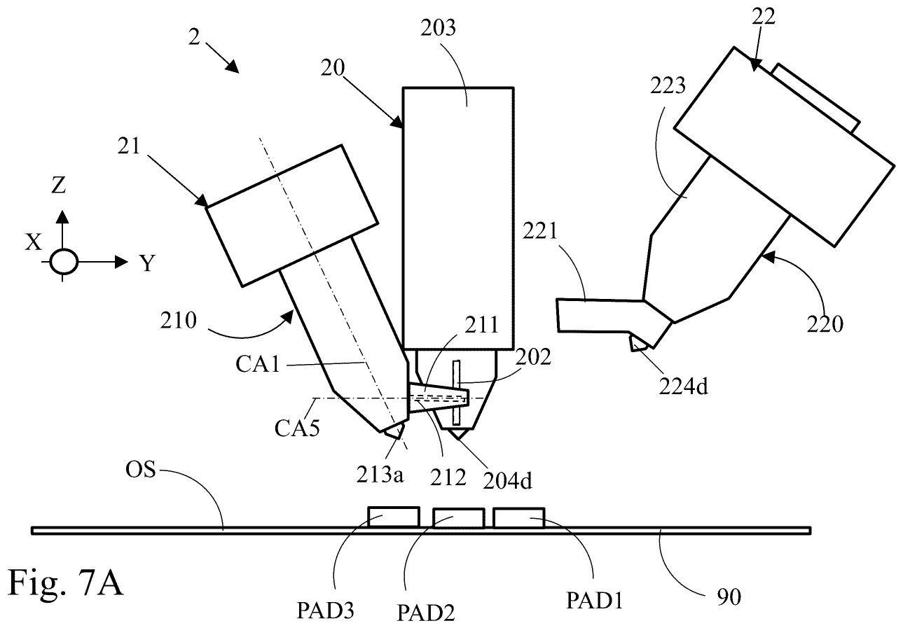

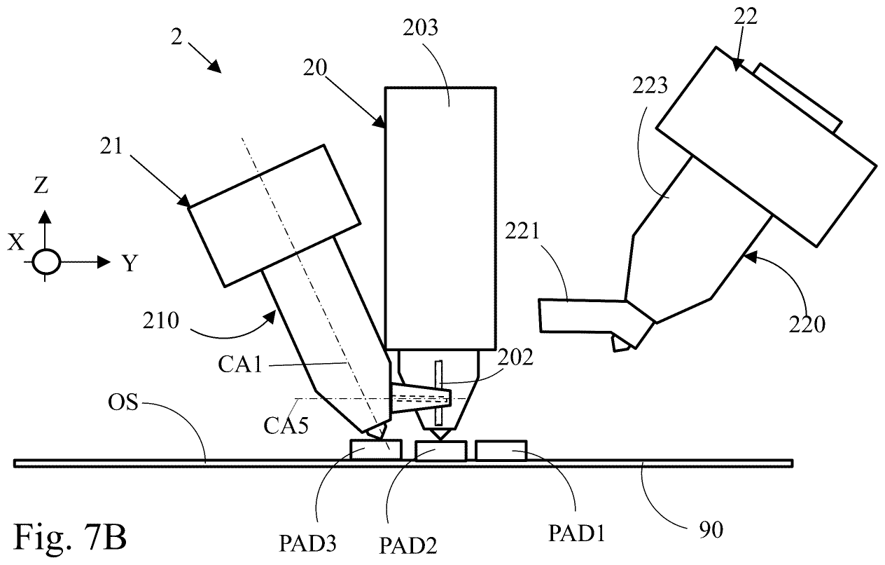

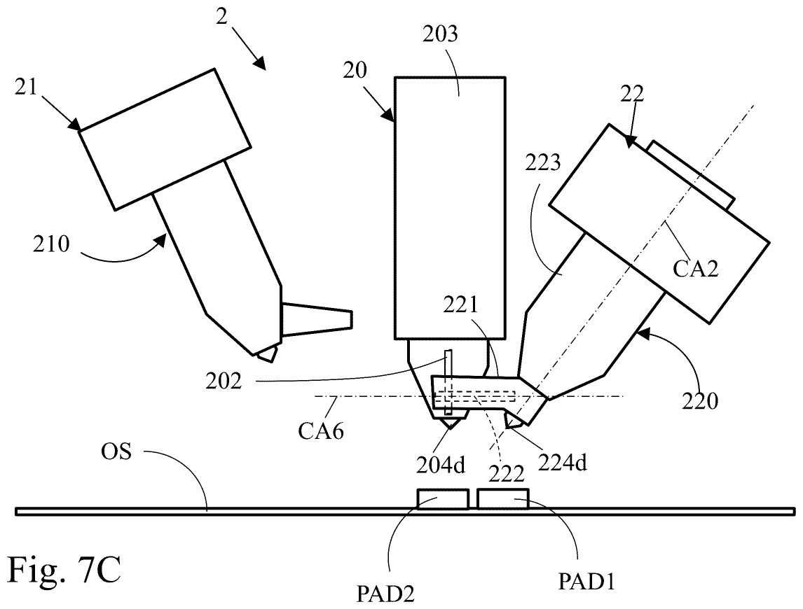

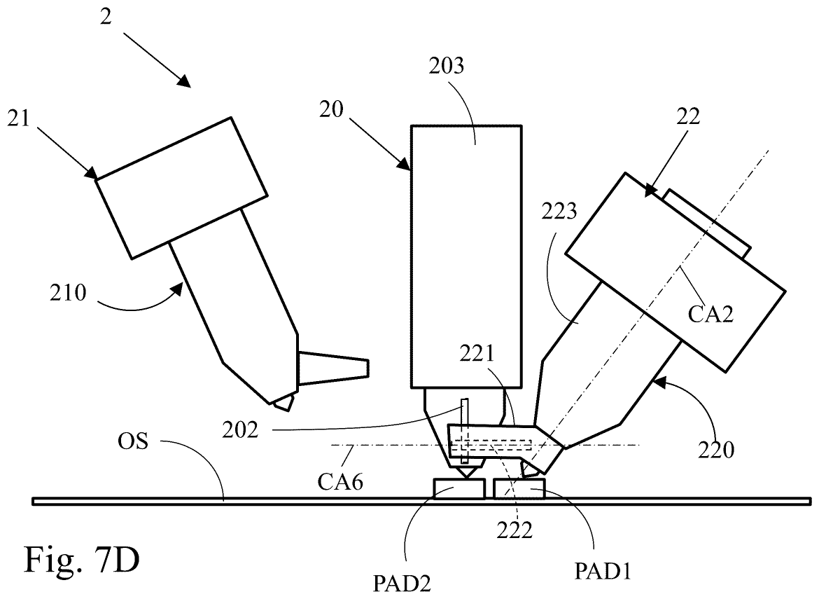

Next, the operation of the position-adjustable probing device is explained as below. Please refer to FIGS. 7A˜7B, which illustrate the action of the stationary probe and first movable probe for testing electrical characteristics of DUT. During the testing, the stationary probe 20 is utilized to contact with the contact pad PAD2 while the first movable probe 21 is utilized to contact with the contact pad PAD3. In the FIG. 7A, since the pitch between the contact pads PAD2 and PAD3 is a known information in advance, the control unit of the probing device can adjust the position of the first movable probe 21 first by controlling the first movable probe 21 to perform the first translation movement according to pitch information and image alignment so as to ensure the pitch between the needle tip 213a and the needle tip 204d of the stationary probe 20 is consistent with the pitch between the contact pads PAD2 and PAD3 and enable the first conductive structure 212 contacts with the conductive structure 202 of the stationary probe 20. The first translation movement can be, but should not be limited to, movement alone single axial direction or dual axial directions. The first translation movement is performed toward direction of the stationary probe 20. In the present embodiment, an included angle greater than zero degree is formed between the central axis CA5 of the first conductive structure 212 and the second central axis CA1 of the first movable probe 21 through the first planar structure 211 that supports the first conductive structure 212 whereby the first conductive structure 212 and the conductive structure 202 of the stationary probe 20 are mutually perpendicular to each other when the first conductive structure 212 electrically contacts with the conductive structure 202 of the stationary probe 20. In one embodiment, the first planar structure 211 will face the supporting surface 201 which can be the sloping surface 201a shown in FIG. 4A and FIG. 4C or the first exterior conductive layer 204c shown in FIG. 4B. After that, as shown in FIG. 7B, the stationary probe 20 and the first movable probe 21 are both moved along the −Z direction so as to electrically contact with the contact pads PAD2 and PAD3, respectively. In the meantime, in order to prevent the second movable probe 22 from interfering with the stationary probe 20 and first movable probe 21, the second movable probe 22 is controlled to be on the +Z axial direction relative to the stationary probe 20 and the first movable probe 21. In order to ensure unnecessary abrasion when the conductive structures electrically contact with each other, in one embodiment, when the first conductive structure 212 electrically contacts with the conductive structure 202 of the stationary probe 20, the central axis CA5 of the first conductive structure 212 is perpendicular to the central axis, e.g., the central axis CA4 shown in FIG. 4A, of the conductive structure 202 of the stationary probe 20.

Please refer to FIGS. 7C and 7D, which illustrates the electrical test on the DUT performed by the stationary probe and the second movable probe. During the test, taking the contact pad PAD2 electrically contacted by the stationary probe 20 and the contact pad PAD1 electrically contacted by the second movable probe 22 as the example, as illustrated in FIG. 7C, since the pitch between the contact pads PAD1 and PAD 2 can be known in advance, the control unit of the probing device can adjust the position of the second movable probe 22 first by controlling the second movable probe 22 to perform the second translation movement according to pitch information and image alignment so as to ensure the pitch between the needle tip 224d and the needle tip 204d of the stationary probe 20 is consistent with the pitch between the contact pads PAD1 and PAD2 and enable the second conductive structure 222 contacts with the conductive structure 202 of the stationary probe 20. The second translation movement can be, but should not be limited to, movement alone single axial direction or dual axial directions. The second translation movement is performed toward direction of the stationary probe 20. In the present embodiment, an included angle larger than zero degree is formed by the central axis CA6 of the second conductive structure 222 and third central axis CA2 of the second movable probe 22 through the second planar structure 221 that supports the second conductive structure 222 whereby the second conductive structure 222 and the conductive structure 202 of the stationary probe 20 are mutually perpendicular to each other when the second conductive structure 222 is electrically contacts with the conductive structure 202 of the stationary probe 20. In one embodiment, the second planar structure 221 will face the supporting surface 201 which can be the sloping surface 201a shown in FIG. 4A and FIG. 4C or the first exterior conductive layer 204c shown in FIG. 4B. After that, as shown in FIG. 7D, the stationary probe 20 and the second movable probe 22 are both moved along the −Z direction so as to electrically contact with the contact pads PAD1 and PAD2, respectively. In the meantime, in order to prevent the first movable probe 21 from interfering with the stationary probe 20 and second movable probe 22, the first movable probe 21 is controlled to be on the +Z axial direction relative to the stationary probe 20 and the second movable probe 22. In order to ensure unnecessary abrasion when the conductive structures electrically contact with each other, in one embodiment, when the second conductive structure 221 electrically contacts with the conductive structure 202 of the stationary probe 20, the central axis CA6 of the second conductive structure 221 is perpendicular to the central axis, e.g., the central axis CA4 shown in FIG. 4A, of the conductive structure 202 of the stationary probe 20.

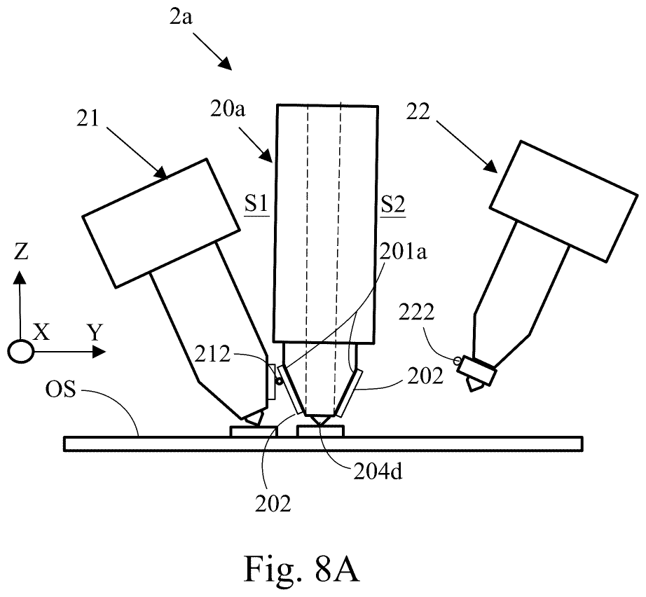

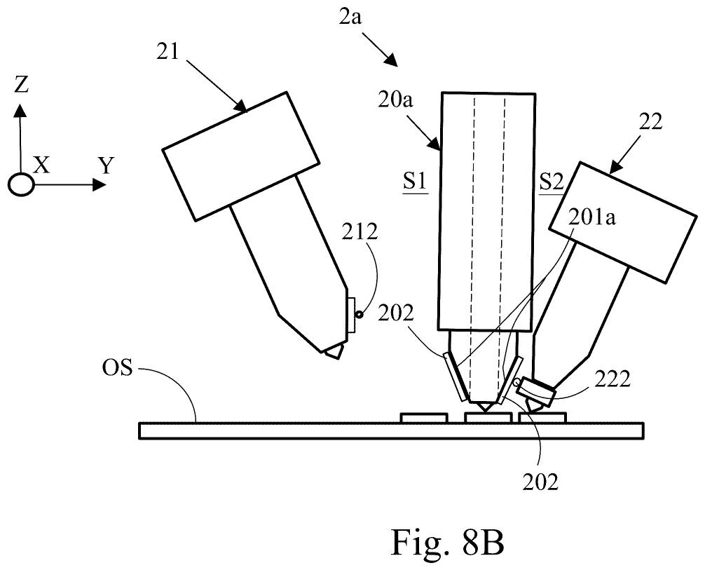

In another alternative embodiment shown as FIGS. 8A and 8B, which illustrate position-adjustable probing device according to another embodiment of the present invention. In the probing device 2a shown in FIGS. 8A and 8B, the area near the needle tip 20d located at the first side S1 and second side S2 of the stationary probe 20a has a sloping surface 201a, respectively. Each sloping surface 201a has the conductive structure 202 formed thereon. In the present embodiment, the conductive structures 202 are corresponding to the first movable probe 21 and the second movable probe 22, respectively. The first conductive structure 212 of the first movable probe 21 electrically contacts with the conductive structure 202 located at the first side S1 of the stationary probe 20a, while the second conductive structure 222 electrically contacts with the conductive structure 202 located at the second side S2 of the stationary probe 20a. It is noted that abrasion of the conductive structure 202 could be reduced for increasing lifetime of the stationary probe 20a through the way that the first conductive structure 212 and the second conductive structure 222 electrically contacts with the corresponding conductive structures 202 of the stationary probe 20a. It is noted that the sloping surface 201a is similar to the above-mentioned embodiments, and it will not be further described hereinafter.

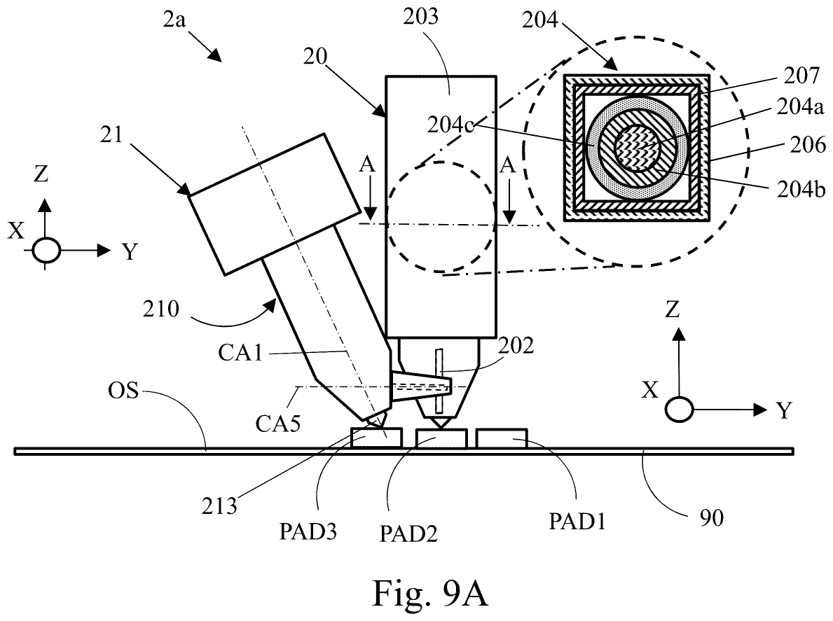

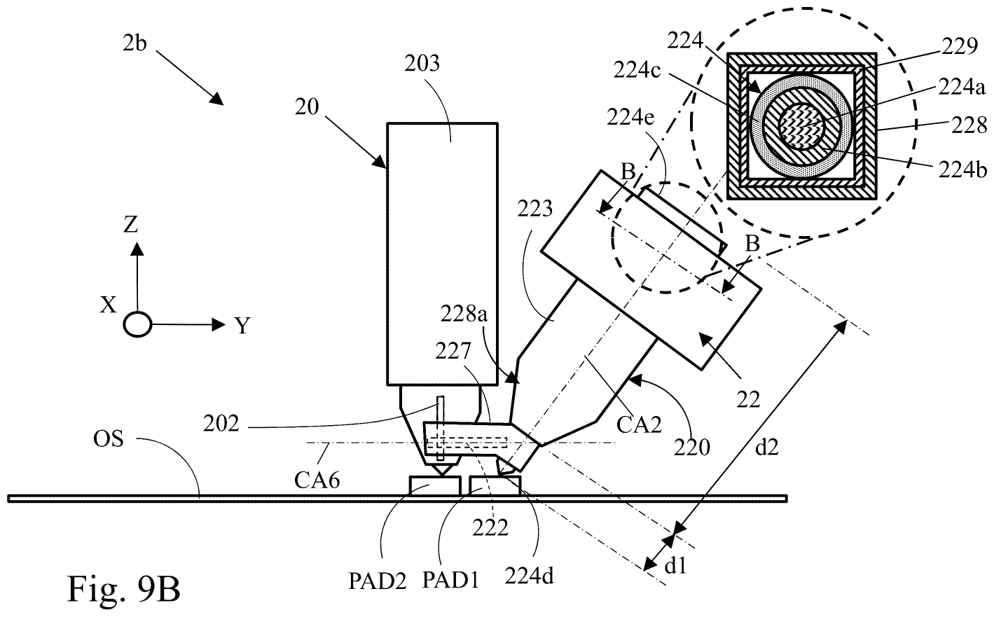

Please refer to FIG. 9A, which illustrates position-adjustable probing device according to another embodiment of the present invention. In the present embodiment, the position-adjustable probing device 2a comprises a stationary probe and movable probe for adjusting the pitch between the stationary probe and movable probe through the translation movement. In the present embodiment, the stationary probe 20 is illustrated as FIG. 3A, and the movable probe can be the first movable probe 21 illustrated as the embodiment shown in FIGS. 5A-5B or the second movable probe 22 illustrated as the embodiment shown in FIG. 6A-6B. In order to conveniently explaining the embodiment, the first movable probe 21 having needle core extending along the second central axis CA1 and extending structure is used as the exemplary example. In the present embodiment, the needle core is the ground needle core 213, and the extending structure is the first extending structure 216, which protrudes toward one direction from the ground needle core 213. The stationary probe 20 comprises a first coaxial structure 204 which comprises a first needle core 204a extending from the first central axis CA0, and the first dielectric layer 204b, and first exterior conductive layer 204c, both of which are coaxially surrounded the first needle core 204a. The first exterior conductive layer 204c is utilized to electrically contact with the first extending structure 216 of the first movable probe 21. After the first movable probe 21 is utilized to adjust the pitch between the first movable probe 20 and the first movable probe 21 through the translation movement, the first exterior conductive layer 204c electrically contacts with the first extending structure 216 of the first movable probe 21. During the process that the first movable probe 21 performs the translation movement, the first extending structure 216 does not contact with the first exterior conductive layer 204c. As the illustration shown in the FIG. 9A and FIG. 7A, during the process that the first movable probe 21 performs the translation movement, the first conductive structure 212 formed on the first extending structure 216 does not contact with conductive structure 202 of the stationary probe 20. Furthermore, the first extending structure 216 does not contact with the first exterior conductive layer 204c so as to prevent the contact interface of the first movable probe 21 and stationary probe 20, e.g., first conductive structure 212 and conductive structure 202 of the stationary probe, from being mutually rubbed with each other thereby inducing the abrasion and shortening the lifetime.

In one embodiment, like the embodiment shown in FIG. 4A, the stationary probe 20 further comprises a holding part 205 arranged on the first exterior conductive layer 204c for electrically connecting to the first exterior conductive layer 204c. The structure of the holding part 205 is the as the structure as previously described. Like the illustration shown in FIG. 4A and FIG. 9A, after the pitch between the first movable probe 21 and the stationary probe 20 is adjusted by the first movable probe 21 through the translation movement, the sloping surface 201a is utilized to electrically contact with the first extending structure 216 of the first movable probe 21. One end part of the first needle core 204a is the needle tip 204d, and the bottom end part 205c is closer to the needle tip 204d of the first needle core 204a than the top end part 205b, wherein a first distance d3 on the bottom end part 205c is defined from the first exterior conductive layer 204c to the sloping surface 201a, a second distance d4 on the top end part 205b is defined from the first exterior conductive layer 204c to the sloping surface 201a, and the second distance d4 is larger than the first distance d3. The holding part 205 further comprises conductive structure 202 which can be a cylindrical rod-like conductor structure or has as a plurality of ball-like protrusions formed by linear arrangement described previously and it will not be described hereinafter.

Please refer to FIG. 9B, which illustrates the position-adjustable probing device according to another embodiment of the present invention. In the present embodiment, the position-adjustable probing device 2b comprises a stationary probe 20 which is secured in a fixed position without moving, and the pitch between the movable probe and the stationary probe is adjusted through translation movement of the movable probe. The structure of the stationary probe 20 is described previously and it will not be described hereinafter. The movable probe can be the first movable probe 21 like the embodiment shown in FIGS. 5A-5B, or the second movable probe 22 like the embodiment shown in FIGS. 6A-6B. The following embodiments are explained by using the second movable probe 22 shown in FIG. 6A. The second movable probe 22 comprises the second needle core 224a extending along the third central axis CA2, and the second extending structure 227. The second needle core 224a protrudes toward one direction. The structure of second extending structure 227, like the embodiment described previously, comprises a top surface 221a and bottom surface 221b, wherein one end of the second needle core 224a is the needle tip 224d, the bottom surface 221b is closer to the needle tip 224d of the second needle core 224a than the top surface 221a, and a second included angle θ2 is formed by the needle tip 224d of the second needle core 224a and the bottom surface 221b. The second extending structure 227 is electrically contacted with the first exterior conductive layer 204c of the stationary probe 20. In one embodiment, after the pitch between the second movable probe 22 and the stationary probe 20 is adjusted through the translation movement, the second extending structure 227 is utilized to electrically contact with the first exterior conductive surface 204c of the stationary probe 20. It is noted that after adjusting the pitch between the movable probe whether the first movable probe 21 or the second movable probe 22, and the stationary probe 20 during the adjusting process of the translation movement of the movable probe, e.g., the first movable probe 21 or second movable probe 22, the extending structure, e.g., the first extending structure 216 or the second extending structure 227 will not electrically connect to the first exterior conductive layer 204c, which is described previously and it will not be described hereinafter.

Another end on the third central axis CA2 of the second needle core 224a is the needle tail 224e, and the distance d1 from second extending structure 227 to the needle tip 224d of the second needle core 224a is smaller than the distance d2 from the second extending structure 227 to the needle tail 224e of the second needle core 224a. The second movable probe 22 comprises the second isolation casing 228 covering the second exterior conductive layer 224c. The second isolation casing 228 comprises a partial tapered structure 228a arranged between the needle tip 224d and the needle tail 224e of the second needle core 224a, while the second extending structure 227 is arranged between the partial tapered structure 228a and the needle tip 224d of the second needle core 224a.

In another alternative embodiment, the movable probe can also be the first movable probe 21 illustrated in FIG. 5A. The first movable probe 21 comprises a ground needle core 213 extending along the second central axis CA1, and a first extending structure 216 protruding toward one direction from the first needle core 213 wherein the structure of the first extending structure 216 is describe previously, and it will not be described hereinafter. One end of the ground needle core 213 is the needle tip 213a, and the bottom surface 216b is closer to the needle tip 213a of the ground needle core 213 than the top surface 216a. A first included angle θ1 is formed between the needle tip 213a of the ground needle core 213 and the bottom surface 216b. The first extending structure 216 is utilized to electrically contact with the first exterior conductive layer 204c. In one embodiment, after the pitch between the first movable probe 21 and the stationary probe 20 is adjusted through translation movement of the first movable probe 21, the first extending structure 216 is electrically contacted with the first exterior conductive layer 204c of the stationary probe 20. In the present embodiment, the first movable probe 21 comprises a metal block 215 electrically connected to the ground needle core 213. The end part of the metal block 215 is the needle tip 213a of the ground needle core 213 on the second central axis CA1 of the ground needle core 213. The metal block 215 comprises a partial tapered structure 215a formed between another end part of the metal block 215 and the needle tip 213a, and the first extending structure 216 protrudes from a lateral side of the partial tapered structure 215a.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A position-adjustable probing device, comprising:
a stationary probe, comprising a first coaxial structure comprising a first needle core extending along a first central axis, and a first dielectric layer and a first exterior conductive layer, both coaxially surrounded the first needle core, wherein the first coaxial structure comprises a first side and a second side relative to the first central axis;
a first movable probe, arranged at the first side of the stationary probe, the first movable probe further comprising a ground needle core extending along a second central axis, and a first extending structure, coupled to the ground needle core, protruding toward one specific direction from the ground needle core, wherein the first extending structure further comprises a first planar structure, a first top surface and a first bottom surface, the first planar structure is formed between the first top surface and the first bottom surface, one end of the ground needle core is a needle tip, the first bottom surface is closer to the needle tip of the ground needle core than the first top surface, a first included angle is formed between the needle tip of the ground needle core and the first bottom surface, and the first planar structure electrically contacts with the stationary probe through a first translation movement of the first movable probe; and
a second movable probe, arranged at the second side of the stationary probe, comprising a second coaxial structure, and a second extending structure, the second coaxial structure comprising a second needle core extending along a third central axis, and a second dielectric layer, and a second exterior conductive layer, both coaxially surrounded the second needle core, the second extending structure, coupled to the second exterior conductive layer, protruding toward one specific direction from the second needle core, wherein the second extending structure further comprises a second planar structure, a second top surface and a second bottom surface, the second planar structure is formed between the second top surface and the second bottom surface, one end of the second needle core is a needle tip, the second bottom surface is closer to the needle tip of the second needle core than the second top surface, a second included angle is formed between the needle tip of the second needle core and the second bottom surface, and the second planar structure electrically contacts with the stationary probe through a second translation movement of the second movable probe.

2. The device of claim 1, wherein another end of the second needle core along the third central axis is a needle tail, and the second extending structure arranged on the second coaxial structure comprises a boundary surface, wherein a distance defined from the boundary surface to the needle tip of the second needle core is smaller than a distance defined from the boundary surface to the needle tail of the second needle core.

3. The device of claim 2, wherein the second movable probe further comprises a second isolation casing enclosing the second exterior conductive layer, wherein the second isolation casing comprises a partial tapered structure formed between the needle tip of the second needle core and the needle tail of the second needle core, and the second extending structure is arranged between the partial tapered structure and the needle tip of the second needle core.

4. The device of claim 1, wherein the first movable probe further comprises a metal block electrically connected to the ground needle core, and one lateral side of the metal block is protruded out of the first extending structure.

5. The device of claim 4, wherein on the second central axis of the ground needle core, one end part of the metal block is the needle tip of the ground needle core, the metal block further comprises a partial tapered structure formed between another end part of the metal block and the needle tip of the ground needle core, and the first extending structure is protruded out from one lateral side of the partial tapered structure.

6. The device of claim 1, wherein the stationary probe further comprises a holding part arranged on the first exterior conductive layer for electrically connecting to the first exterior conductive layer, the holding part further comprising a sloping surface, an top end part and a bottom end part, wherein the sloping surface is arranged between the top end part and bottom end part, one end of the first needle core is a needle tip, the bottom end part is closer to the needle tip of the first needle core than the top end part, a first distance on the bottom end part is defined from the first exterior conductive layer to the sloping surface, and a second distance on the top end part is defined from the first exterior conductive layer to the sloping surface, wherein the second distance is larger than the first distance.

7. The device of claim 6, wherein the stationary probe further comprises a conductive structure arranged on the sloping surface, the first movable probe further comprises a first conductive structure arranged on the first planar structure, and the conductive structure of stationary probe is in electrical point contact with the first conductive structure when the conductive structure is electrically contacted with the first conductive structure.

8. The device of claim 6, wherein the stationary probe further comprises a conductive structure, the second movable further comprises a second conductive structure, the conductive structure is arranged on the sloping surface, the second conductive structure is arranged on the second planar structure, and the conductive structure of stationary probe is in electrical point contact with the second conductive structure when the conductive structure is electrically contacted with the second conductive structure.

9. The device of claim 7, wherein the conductive structure is a cylindrical rod-like conductor structure or has a plurality of ball-like protrusions formed by linear arrangement.

10. The device of claim 7, wherein the first conductive structure is a cylindrical rod-like conductor structure or has a plurality of ball-like protrusions formed by linear arrangement.

11. The device of claim 8, wherein the second conductive structure is a cylindrical rod-like conductor structure or has a plurality of ball-like protrusions formed by linear arrangement.

12. The device of claim 1, wherein the stationary probe further comprises a first isolation casing for enclosing the first exterior conductive layer, and the second movable probe comprises a second isolation casing for enclosing the second exterior conductive layer.

13. The device of claim 12, wherein a first reinforcement structure is formed between the first exterior conductive layer and the first isolation casing, and a second reinforcement structure is formed between the second isolation casing and the second exterior conductive layer.

14. A stationary probe of a position-adjustable probing device, in which the position-adjustable probing device comprises a movable probe for adjusting a pitch between the movable probe and the stationary probe through a translation movement, the movable probe further comprises a needle core extending along a central axis, and an extending structure protruding toward one specific direction from the needle core, wherein the stationary probe further comprises:
a stationary probe, comprising a first coaxial structure comprising a first needle core extending along a first central axis, and a first dielectric layer and a first exterior conductive layer, both coaxially surrounded the first needle core, wherein the first exterior conductive layer is configured to electrically contacted with the extending structure of the movable probe.

15. The stationary probe of claim 14, wherein after the pitch between the movable probe and the stationary probe is adjusted through the translation movement, the first exterior conductive layer is electrically contacted with the extending structure of the movable probe.

16. The stationary probe of claim 14, further comprising a holding part arranged on the first exterior conductive layer so as to electrically connected to the first exterior conductive layer, wherein the holding part further comprises a sloping surface, a top end part and a bottom end part, the sloping surface is arranged between the top end part and bottom end part, the sloping surface is utilized to contact with the extending structure of the movable probe after a pitch between the movable probe and the stationary probe is adjusted through the translation movement, one end of the first needle core is a needle tip, the bottom part is closer to the needle tip than the top part, a first distance on the bottom end part is defined from the first exterior conductive layer to the sloping surface, and a second distance on the top end part is defined from the first exterior conductive layer to the sloping surface, wherein the second distance is larger than the first distance.

17. The stationary probe of claim 16, further comprising a conductive structure arranged on the sloping surface wherein the conductive structure is a cylindrical rod-like conductor structure or has as a plurality of ball-like protrusions formed by linear arrangement.

18. A movable probe of a position-adjustable probing device, in which the position-adjustable probing device comprises a stationary probe arranged at a stationary position, a pitch between the movable probe and the stationary probe through a translation movement, and the stationary probe further comprises a coaxial structure having a first needle core extending from a first central axis, and a first dielectric layer and a first exterior conductive layer, both coaxially surrounded the first needle core, wherein the movable probe further comprises:
a needle core extending from a central axis, and a extending structure protruding toward one specific direction from the needle core, the extending structure further comprising a planar structure, a top surface and a bottom surface, wherein the planar structure is arranged between the top surface and the bottom surface, one end of the needle core is a needle tip, the bottom surface is closer to the needle tip of the needle core than the top surface, an included angle is formed between the needle tip of the needle core and the bottom surface, and the extending structure is utilized to electrically contact with the first exterior conductive layer.

19. The movable probe of claim 18, wherein after the pitch between the movable probe and the stationary probe is adjusted by the movable probe through the translation movement, the extending structure is electrically contacted with the first exterior conductive layer.

20. The movable probe of claim 18, wherein the movable probe further comprises a first movable probe comprising a ground needle core extending from a second central axis of the first movable probe, and first extending structure, in which the needle core of the movable probe is the ground needle core, the extending structure of the movable probe is the first extending structure coupled to the ground needle core, and the first extending structure is moved to electrically contact with the first exterior conductive layer after the pitch between first movable probe and the stationary probe is adjusted by the first movable probe through the translation movement, wherein the first extending structure further comprises a first planar structure, a first top surface, and a first bottom surface, the planar structure is the first planar structure, the top surface is the first top surface, the bottom surface is the first bottom surface, a first included angle is formed between the needle tip of the ground needle core and the first bottom surface, and the included angle is the first included angle.

21. The movable probe of claim 20, wherein the first movable probe comprises a metal block electrically connected to the ground needle core, one end part of the metal block on the second central axis of the ground needle core is the needle tip of the ground needle core, the metal block further comprises a partial tapered structure arranged between the another end part of the metal block and the needle tip of the ground needle core, and the first extending structure is protruded from one lateral side of the partial tapered structure.

22. The movable probe of claim 18, wherein the movable probe further comprises a second movable probe comprising a second coaxial structure having a second needle core extending along a third central axis, and a second dielectric layer and a second exterior conductive layer, both coaxially surrounded the second needle core, and a second extending structure, the needle core of the movable probe is the second needle core, the extending structure of the movable probe is the second extending structure, the second extending structure is configured to be moved to electrically contact with the first exterior conductive layer after the pitch between the second movable probe and the stationary probe is adjusted by the second movable probe through the translation movement, the second extending structure is coupled to the second exterior layer, the second extending structure comprises a second planar structure, a second top surface, and the second bottom surface, the planar structure is the second planar structure, the top surface is the second top surface, the bottom surface is the second bottom surface, a second included angle is defined between the needle tip of the second needle core and the second bottom surface, and the included angle is the second included angle.
